(19) United States
(12) Patent Application Publication
(10) Pub. No.: US 2026/0255820 A1
(43) Pub. Date: Aug. 27, 2026

(54) Display Substrate and Display Apparatus

(71) Applicants: Chengdu Boe Optoelectronics Technology Co., Ltd., Chengdu, Sichuan (CN); BOE Technology Group Co., Ltd., Chaoyang District, Bejing (CN)

(72) Inventors: Tiaomei Zhang, Beijing (CN); Jianpeng Wu, Beijing (CN); Wenhui Gao, Beijing (CN); Lang Liu, Beijing (CN); Hongbo Ma, Beijing (CN)

(21) Appl. No.: 18/995,313

(22) PCT Filed: May 14, 2024
(86) PCT No.: PCT/CN2024/093233

§ 371 Date: Jan. 16, 2025

(30) Foreign Application Priority Data
Jun. 30, 2023 (CN) 202310805085.X

(51) Int. Cl. H10K 59/131

(52) U.S. Cl. CPC H10K 59/131

(57) ABSTRACT

A display substrate includes pixel circuits, data lines, first fan-out lines and second fan-out lines. A column of pixel circuits is electrically connected to one data line. The data lines include at least one setting data line. An end of a first fan-out line is electrically connected to a setting data line, and another end of the first fan-out line is electrically connected to a second fan-out line. The display substrate includes pixels each including at least three sub-pixels. Each sub pixel includes one pixel circuit. The pixels include at least one setting pixel. One setting pixel corresponds to at least one second fan-out line. A second fan-out line passes through a region between pixel circuits of two adjacent sub-pixels in a corresponding setting pixel or passes through an out side of an outer pixel circuit of the corresponding setting pixel, and extends to a bonding region.

### CROSS-REFERENCE TO RELATED APPLICATIONS

This application is the United States national phase of International Patent Application No. PCT/CN2024/093233, filed May 14, 2024, and claims priority to Chinese Patent Application No. 202310805085.X, filed Jun. 30, 2023, the disclosures of which are hereby incorporated by reference in their entireties.

### BACKGROUND OF THE INVENTION

### Field of the Invention

The present disclosure relates to the field of display technologies, and in particular, to a display substrate and a display apparatus.

### Description of Related Art

Organic light-emitting diode (OLED) display apparatuses have gradually become one of mainstream products in the display field due to their excellent properties such as self-luminescence, high contrast, wide viewing angle, fast response, applicability to a flexible panel, a wide temperature range for using, a simple structure and a simple process. OLED display substrates can be widely used in terminal products such as smartphones, tablet computers, televisions and wearable devices (e.g. watches). High Pixels Per Inch (PPI) and narrow border are currently an important development direction of OLED display apparatuses.

### SUMMARY OF THE INVENTION

In an aspect, a display substrate is provided. The display substrate has a display area and a bonding region, and the bonding region is located on a side of the display region in a second direction. The display substrate includes: a plurality of pixel circuits, a plurality of data lines, and first fan-out lines and second fan-out lines that are arranged in the display region. The plurality of data lines include at least one setting data line, and the second fan-out lines are closer to a center line, along the second direction, of the bonding region than the at least one setting data line.

The plurality of pixel circuits are arranged in a plurality of rows and a plurality of columns. A row of pixel circuits is arranged in a first direction, and a column of pixel circuits is arranged in the second direction, the first direction and the second direction intersecting. The data lines extend in the second direction. The column of pixel circuits is electrically connected to one of the data lines. The first fan-out lines extend in the first direction, and the second fan-out lines extend in the second direction. An end of a first fan-out line is electrically connected to a setting data line, and another end of the first fan-out line is electrically connected to a second fan-out line.

The display substrate includes a plurality of pixels, each pixel includes at least three sub-pixels, and each sub-pixel includes one pixel circuit. The plurality of pixels include at least one setting pixel, and one setting pixel corresponds to at least one of the second fan-out lines. A second fan-out line passes through a region between pixel circuits of two adjacent sub-pixels in a corresponding setting pixel or passes through an outer side of an outer pixel circuit of the corresponding setting pixel, and extends to the bonding region.

In some embodiments, the display substrate further includes first voltage signal lines extending in the second direction. One setting pixel corresponds to at least one of the first voltage signal lines. A first voltage signal line passes through a region between pixel circuits of two adjacent sub-pixels in a corresponding setting pixel or passes through an outer side of an outer pixel circuit of the corresponding setting pixel.

In some embodiments, one second fan-out line among the at least one of the second fan-out lines corresponding to the setting pixel passes through a region between pixel circuits of a pair of adjacent sub-pixels in the setting pixel, and one first voltage signal line among the at least one of the first voltage signal lines corresponding to the setting pixel passes through a region between pixel circuits of another pair of adjacent sub-pixels in the setting pixel.

In some embodiments, the pixel includes three sub-pixels. The setting pixel corresponds to one second fan-out line and one first voltage signal line, the second fan-out line passes through a region between pixel circuits of a pair of adjacent sub-pixels among three sub-pixels in the setting pixel, and the first voltage signal line passes through a region between pixel circuits of another pair of adjacent sub-pixels among the three sub-pixels in the setting pixel.

In some embodiments, one first voltage signal line among the at least one first voltage signal line corresponding to the setting pixel and one second fan-out line among the at least one second fan-out line corresponding to the setting pixel pass through a region between pixel circuits of a same pair of adjacent sub-pixels.

In some embodiments, the pixel includes three sub-pixels. The setting pixel corresponds to one second fan-out line and one first voltage signal line, and the second fan-out line and the first voltage signal line pass through a region between pixel circuits of a same pair of adjacent sub-pixels among three sub-pixels in the setting pixel.

In some embodiments, the second fan-out line is provided therein with a second disconnected opening, and the second disconnected opening divides the second fan-out line into an effective portion and a redundant portion. An end of the effective portion of the second fan-out line is electrically connected to the first fan-out line, and another end of the effective portion of the second fan-out line extends to the bonding region. The display substrate further includes a first connection portion, and the first voltage signal line and the redundant portion of the second fan-out line are electrically connected through the first connection portion.

In some embodiments, the first voltage signal line and the second fan-out line passing through the region between the pixel circuits of the same pair of adjacent sub-pixels are adjacent to each other; and the first voltage signal line, the second fan-out line and the first connection portion are arranged in the same layer and constitute a one-piece structure.

In some embodiments, the first fan-out line is provided therein with a first disconnected opening, and the first disconnected opening divides the first fan-out line into an effective portion and a redundant portion. An end of the effective portion of the first fan-out line is electrically connected to the setting data line, and another end of the effective portion of the first fan-out line is electrically connected to the effective portion of the second fan-out line. The display substrate further includes a second connection portion; an end of the second connection portion is electrically connected to the redundant portion of the first fan-out line; in a thickness direction of the display substrate, a via hole is provided between the second connection portion and the redundant portion of the second fan-out line; and another end of the second connection portion is electrically connected to the redundant portion of the second fan-out line through the via hole.

In some embodiments, the second connection portion and the redundant portion of the first fan-out line are arranged in the same layer and constitute a one-piece structure.

In some embodiments, the display substrate further includes: a plurality of reference voltage signal lines extending in the second direction. The column of pixel circuits is electrically connected to one of the reference voltage signal lines; among two adjacent columns of pixel circuits, a reference voltage signal line connected to one column of pixel circuits and a data line connected to another column of pixel circuits are arranged close to each other. A second fan-out line is arranged between the reference voltage signal line and the data line that are arranged close to each other.

In some embodiments, a first voltage signal line in the display substrate is arranged between the reference voltage signal line and the data line that are arranged close to each other.

In some embodiments, the display substrate further includes: a substrate, a semiconductor layer disposed on the substrate, and a plurality of auxiliary reference voltage signal lines disposed on a side of the semiconductor layer away from the substrate. An auxiliary reference voltage signal line extends in the first direction and is electrically connected to a reference voltage signal line. A first fan-out line is arranged on a side of the auxiliary reference voltage signal line away from the substrate; and an orthogonal projection of the first fan-out line on the substrate overlaps with an orthogonal projection of the auxiliary reference voltage signal line on the substrate, and overlaps with an orthogonal projection of a part of the semiconductor layer on the substrate.

In some embodiments, the display substrate further includes a plurality of second voltage signal lines extending in the second direction, and the column of pixel circuits is electrically connected to one of the second voltage signal lines. A film layer where the plurality of second voltage signal lines are located is located on a side, away from the substrate, of a film layer where the first fan-out lines are located; and an orthogonal projection of the second voltage signal line on the substrate covers an orthogonal projection of a first disconnected opening of the first fan-out line on the substrate.

In some embodiments, the display substrate further includes a plurality of source-drain conductive layers. A pair of adjacent source-drain conductive layers among the plurality of source-drain conductive layers includes a first setting source-drain conductive layer and a second setting source-drain conductive layer. The first setting source-drain conductive layer is closer to the substrate than the second setting source-drain conductive layer. The first fan-out lines are arranged in the first setting source-drain conductive layer, and the data lines and the second fan-out lines are arranged in the second setting source-drain conductive layer.

In some embodiments, the display substrate further includes: a gate signal line, an enable signal line, an auxiliary first voltage signal line and an auxiliary second voltage signal line that all extend in the first direction. The pixel circuit is electrically connected to the gate signal line and the enable signal line. The auxiliary first voltage signal line is electrically connected to a first voltage signal line, and the auxiliary second voltage signal line is electrically connected to a second voltage signal line.

At least one of the gate signal line, the enable signal line, the auxiliary first voltage signal line and the auxiliary second voltage signal line is arranged in the first setting source-drain conductive layer. An orthogonal projection, on the substrate, of at least one of the gate signal line, the enable signal line, the auxiliary first voltage signal line and the auxiliary second voltage signal line covers an orthogonal projection, on the substrate, of a second disconnected opening of the second fan-out line.

In some embodiments, the first voltage signal lines, the second voltage signal lines and the reference voltage signal lines in the display substrate are all arranged in the second setting source-drain conductive layer.

In some embodiments, the display substrate further includes a first gate layer and a second gate layer. In the display substrate, the semiconductor layer, the first gate layer and the second gate layer are arranged in sequence in a direction away from the substrate and are located between the substrate and the plurality of source-drain conductive layers. The auxiliary reference voltage signal lines in the display substrate are arranged in the second gate layer.

In some embodiments, the plurality of source-drain conductive layers include a first source-drain conductive layer and a second source-drain conductive layer, the first source-drain conductive layer is the first setting source-drain conductive layer, and the second source-drain conductive layer is the second setting source-drain conductive layer.

In some embodiments, the plurality of source-drain conductive layers include a first source-drain conductive layer, a second source-drain conductive layer and a third source-drain conductive layer, the first source-drain conductive layer is the first setting source-drain conductive layer, and the second source-drain conductive layer is the second setting source-drain conductive layer.

In some embodiments, the plurality of source-drain conductive layers include a first source-drain conductive layer, a second source-drain conductive layer and a third source-drain conductive layer, the second source-drain conductive layer is the first setting source-drain conductive layer, and the third source-drain conductive layer is the second setting source-drain conductive layer.

In some embodiments, the at least one setting data line is farther away from the center line, along the second direction, of the bonding region than remaining data lines among the plurality of data lines. The at least one setting data line is entirely located in the display region; and ends of the remaining data lines extend to the bonding region.

In another aspect, a display apparatus is provided. The display apparatus includes the display substrate according to any of the above embodiments, and a circuit board. The circuit board is electrically connected to the display substrate.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a structural diagram of a pixel circuit, in accordance with some embodiments;

FIG. 4 is a structural diagram of a pixel circuit, in accordance with some other embodiments;

FIG. 5 is a partial enlarged structural diagram of a display region AA of a display substrate, in accordance with some embodiments;

FIG. 6 is an enlarged structural diagram of the region D in FIG. 5;

FIG. 7 is an enlarged structural diagram of the region F in FIG. 5;

FIG. 8 is a diagram showing structures of layers from a first source-drain conductive layer to a second source-drain conductive layer in a display substrate, in accordance with some embodiments;

FIG. 9 is an enlarged view showing a structure of the first source-drain conductive layer of the display substrate in the region E in FIG. 8, in accordance with some embodiments;

FIG. 10 is an enlarged view showing a structure of the second source-drain conductive layer of the display substrate in the region E in FIG. 8, in accordance with some embodiments;

FIG. 11 is an equivalent circuit diagram of a pixel circuit, in accordance with some embodiments;

FIG. 12 is a sectional view showing a structure of a display substrate, in accordance with some embodiments;

FIG. 13 is a structural diagram of a semiconductor layer in a display substrate, in accordance with some embodiments;

FIG. 14 is a diagram showing structures of layers from a semiconductor layer to a second gate layer in a display substrate, in accordance with some embodiments; and

FIG. 15 is a diagram showing structures of layers from a semiconductor layer to a first source-drain conductive layer in a display substrate, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that two or more components are in direct physical or electrical contact with each other. The term “coupled” or “communicatively coupled” may also indicate that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

As used herein, the term “if” is optionally construed as “when” or “in a case where” or “in response to determining” or “in response to detecting”, depending on the context. Similarly, depending on the context, the phrase “if it is determined that” or “if [a stated condition or event] is detected” is optionally construed as “in a case where it is determined that”, “in response to determining that”, “in a case where [the stated condition or event] is detected” or “in response to detecting [the stated condition or event]”.

The phrase “applicable to” or “configured to” used herein has an open and inclusive meaning, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or value exceeding those stated.

The term such as “about,” “substantially,” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

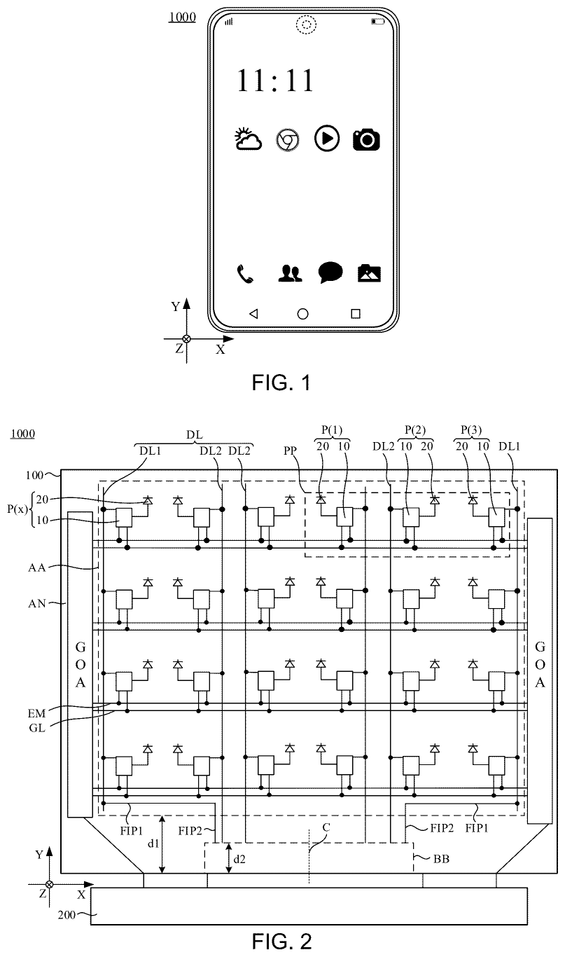

In embodiments of the present disclosure, FIGS. 1 and 2 are each a plan view showing a structure of a display apparatus 1000. In order to clearly describe the connection between a display substrate 100 and a circuit board 200, FIG. 2 shows the circuit board 200 on the same side as a display region AA of the display substrate 100. It will be noted that in the final display substrate 100, the circuit board 200 is bent to another side.

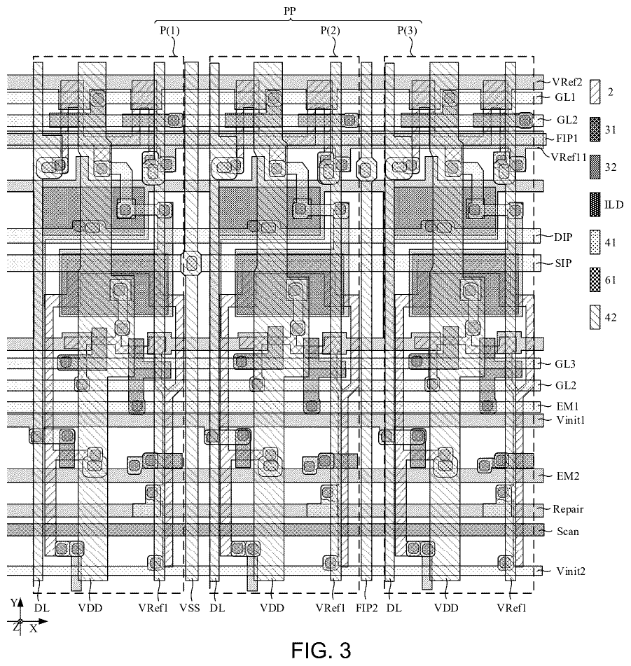

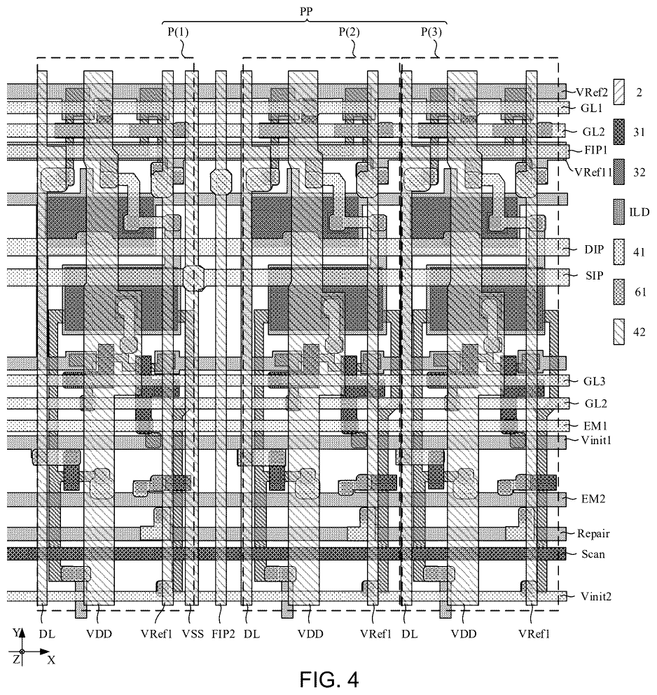

In order to clearly describe the relative positional relationship between second fan-out lines FIP2, first voltage signal lines VSS and pixel circuits 10, FIGS. 3 and 4 only illustrate structures of some pixel circuits 10 in the display substrate 100. The number of pixel circuits 10 included in the actual display substrate 100 is not limited to that shown in the figures. In addition, structures of film layers included in the display substrate 100 include but are not limited to structures of film layers shown in the figures.

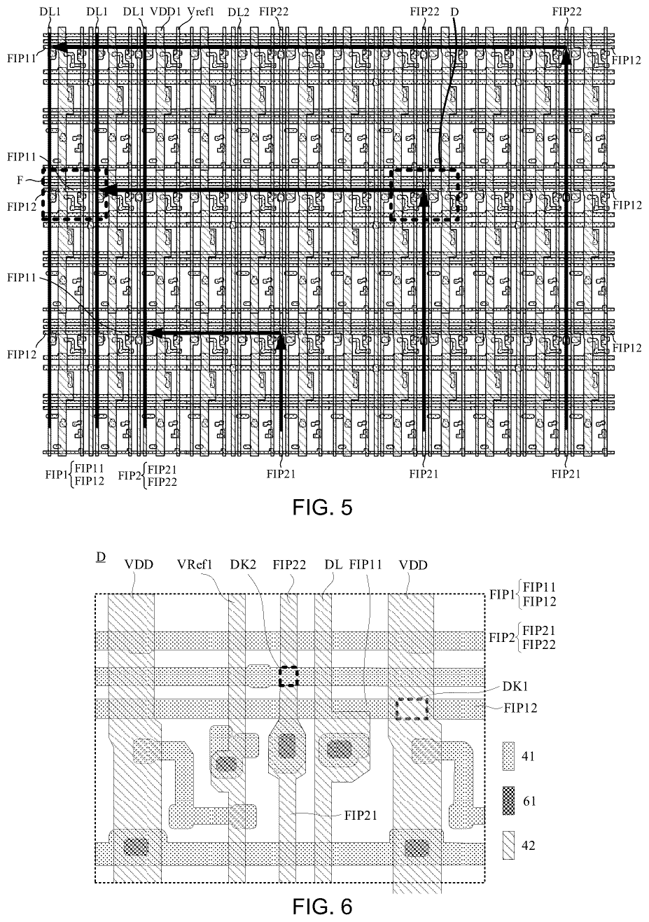

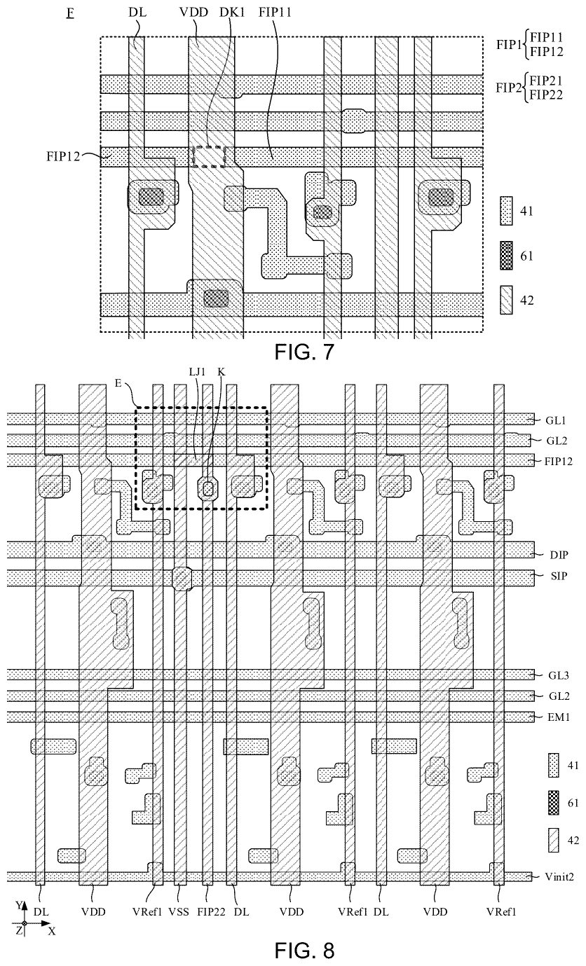

In order to clearly describe transmission paths of the data signal between the setting data line DL1, the first fan-out line FIP1 and the second fan-out line FIP2, FIG. 5 is a partial enlarged view of the display region AA. A direction indicated by a vertical arrow in FIG. 5 is a transmission path of a data signal in the bonding region BB transmitted by the second fan-out line FIP2, and a direction indicated by a horizontal arrow in FIG. 5 is a transmission path of the data signal transmitted from the second fan-out line FIP2 to the first fan-out line FIP1. FIG. 5 illustrates transmission paths of data signals of three setting data lines DL1. FIG. 6 is an enlarged structural diagram of the region D in FIG. 5. FIG. 7 is an enlarged structural diagram of the region F in FIG. 5.

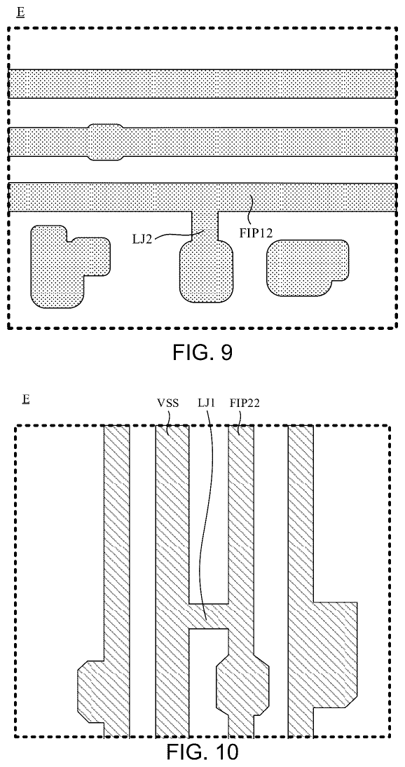

In order to clearly describe the connection between the redundant portion FIP12 of the first fan-out line FIP1, the redundant portion FIP22 of the second fan-out line FIP2 and the first voltage signal line VSS, FIG. 8 only shows structures of layers from a first source-drain conductive layer to a second source-drain conductive layer. FIG. 9 is an enlarged view showing a structure of the first source-drain conductive layer of the display substrate in the region E in FIG. 8. FIG. 10 is an enlarged view showing a structure of the second source-drain conductive layer of the display substrate in the region E in FIG. 8.

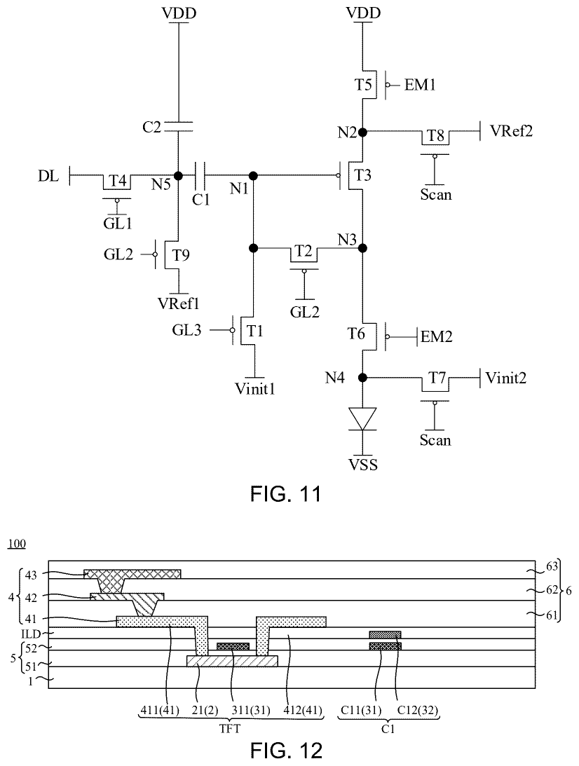

FIG. 11 is an equivalent circuit diagram of a pixel circuit, in accordance with some embodiments. FIG. 12 is a sectional view showing a structure of a display substrate, in accordance with some embodiments.

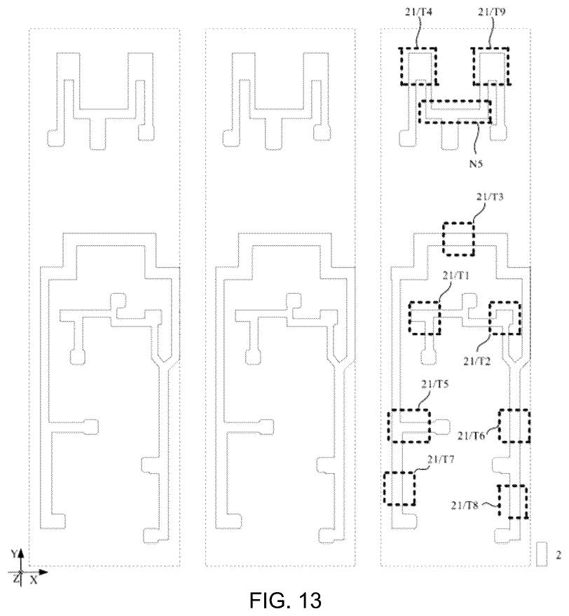

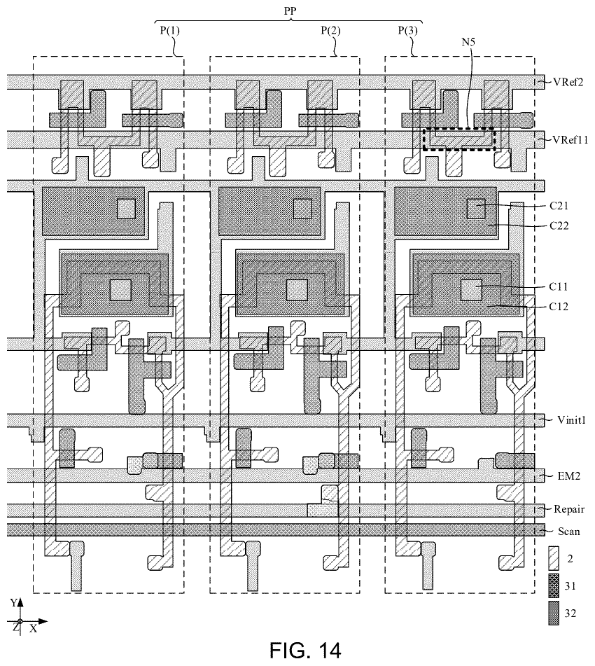

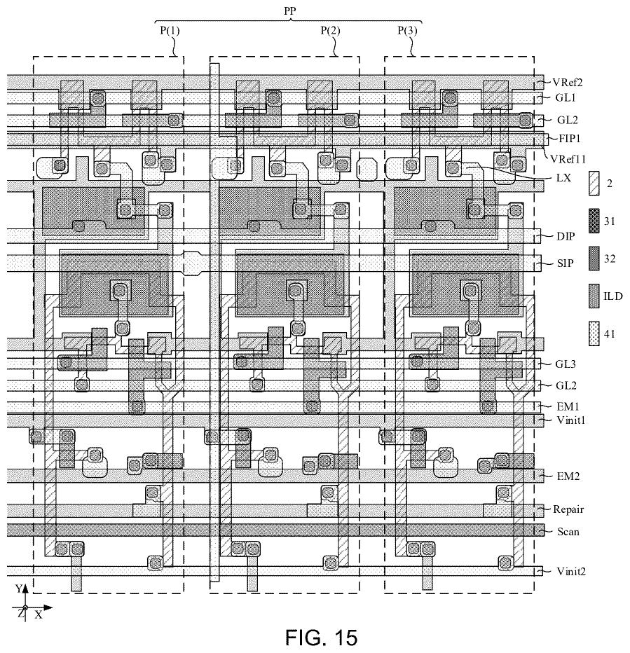

FIG. 13 is a plan view showing a structure of a semiconductor layer in a display substrate, in accordance with some embodiments. FIG. 14 is a diagram showing structures of layers from a semiconductor layer to a second gate layer in a display substrate, in accordance with some embodiments. FIG. 15 is a diagram showing structures of layers from a semiconductor layer to a first source-drain conductive layer in a display substrate, in accordance with some embodiments.

It will be noted that, in order to clearly describe the patterned design of each film layer and the corresponding relationship between the film layers, FIGS. 3 to 10 and 13 to 15 are enlarged views showing only structures of film layers corresponding to partial regions of some sub-pixels in the display substrate. The actual structures of film layers of the display substrate 100 may also include structures of other film layers. The patterned design of each film layer includes but is not limited to that shown in the figures, and may also include other designs.

In order to clearly describe the connections between functional film layers, the insulating dielectric layer ILD and the first planarization layer 61 shown in FIGS. 3, 4, 6 to 8, 14 and 15 are via holes in the insulating dielectric layer ILD and the first planarization layer 61. In the actual structures of the film layers, the insulating dielectric layer ILD and the first planarization layer 61 are whole layers, and the insulating dielectric layer ILD and the first planarization layer 61 are provided therein with via holes at positions shown in the figures. Thus, portions of a second gate layer 32 and a first source-drain conductive layer 41 that need to be electrically connected may be connected correspondingly through via holes, and portions of the first source-drain conductive layer 41 and a second source-drain conductive layer 42 that need to be electrically connected may be connected correspondingly through via holes.

As shown in FIG. 1, some embodiments of the present disclosure provide a display apparatus 1000. The display apparatus 1000 may be any apparatus that displays images whether in motion (e.g., videos) or stationary (e.g., still images), and whether textual or graphical. More specifically, it is expected that the embodiments may be implemented in or associated with a plurality of electronic devices. The plurality of electronic devices include, but are not limited to, televisions (TVs), mobile telephones, wireless devices, personal digital assistants (PDAs), augmented reality (AR) devices, virtual reality (VR) devices, hand-held or portable computers, GPS receivers/navigators, cameras, MP4 video players, video cameras, game consoles, clocks, calculators, TV monitors, flat panel displays, computer monitors, car displays (such as odometer displays, etc.), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc. For example, as shown in FIG. 1, the display apparatus 1000 may be a cellphone.

From the perspective of the light-emitting type of the display apparatus 1000, the display apparatus 1000 may be an organic light-emitting diode (OLED) display apparatus or organic electroluminescence display apparatus, a quantum dot light-emitting diode (QLED) display apparatus, or a mini light-emitting diode or micro light-emitting diode (MLED) display apparatus. From the perspective of the form of the display apparatus 1000, the display apparatus 1000 may be a flat display apparatus, a curved display apparatus, or a foldable display apparatus. From the perspective of the shape of the display apparatus 1000, the display apparatus 1000 may be rectangular or circular. There is no limitation on this, and adaptive design may be made according to actual needs.

Some embodiments of the present disclosure are schematically described below by taking an example in which the display apparatus is a rectangular and flat OLED display apparatus. However, the implementations of the present disclosure include but are not limited to this, and any other display apparatuses can also be considered as long as the same technical concept is applied.

In some embodiments, as shown in FIG. 2, the display apparatus 1000 includes a display substrate 100 and a circuit board 200. The circuit board 200 is electrically connected to the display substrate 100.

For example, the circuit board 200 is configured to transmit driving signals to the display substrate 100 to drive the display substrate 100 to realize image display.

For example, the circuit board 200 may include driving circuits such as a timing controller (TCON), a power management chip DC/DC, and an adjustable resistance voltage division circuit (for generating Vcom). The circuit board 200 may also include other circuit structures, which are not listed here one by one.

In some embodiments, the display apparatus 1000 may further include an under-screen camera, an under-screen fingerprint recognition sensor and the like, so that the display apparatus 1000 is capable of implementing various functions such as photographing, video recording, fingerprint recognition, or face recognition. There is no limitation on this, and adaptive design may be made according to actual needs.

In some embodiments, as shown in FIG. 2, the display substrate 100 has a display region AA and a peripheral region AN that is at least located on a side of the display region AA in a second direction Y. The display substrate 100 includes a plurality of pixels P disposed in the display region AA, and each pixel P includes at least three sub-pixels P(x).

For example, the plurality of pixels P are arranged in a plurality of rows and a plurality of columns.

For example, as shown in FIG. 2, the display region AA is a region of the display substrate 100 for displaying images. The sub-pixels P(x) are the minimum light-emitting units in the display substrate 100, and the sub-pixels P(x) are used for displaying images.

In some examples, the plurality of sub-pixels P(x) emit light of the same color, and the display substrate 100 may further include a color filter layer disposed on a light exit side of the plurality of sub-pixels P(x). That is, the display substrate 100 adopts a CF on Encapsulation (COE) structure.

For example, the plurality of sub-pixels P(x) all emit color light (such as white light, red light, green light or blue light). In this case, the color light emitted by the sub-pixels P(x) remains the same color light after passing through the color filter layer, or is converted into other color light for emission. Therefore, when the plurality of sub-pixels P(x) emit light of the same color, the display substrate 100 can realize multi-color light emission.

In some other examples, the plurality of sub-pixels P(x) emit light of different colors. For example, the plurality of sub-pixels P(x) include red sub-pixels for emitting red light, green sub-pixels for emitting green light, and blue sub-pixels for emitting blue light. Therefore, the display substrate 100 realizes multi-color light emission.

It will be noted that each pixel P includes at least three sub-pixels P(x). That is, each pixel P may include three, four or more sub-pixels P(x). The sub-pixels P(x) included in each pixel P may be a row of sub-pixels P(x), a column of sub-pixels P(x), or a group of sub-pixels P(x). A group of sub-pixels P(x) may be multiple sub-pixels P(x) adjacent to each other, and the multiple sub-pixels P(x) adjacent to each other are arranged in a row, a column, an L-shape, a rectangle, a diamond, etc.

In addition, light emitting areas of the sub-pixels P(x) included in each pixel P may be the same or different. This is only an exemplary description and is not intended to limit the present disclosure, and adaptive design may be made according to actual needs.

Next, the sub-pixels P(x) included in each pixel P being arranged in a row in a first direction X is taken as an example for description.

In some embodiments, as shown in FIG. 2, the peripheral region AN is arranged around the display region AA. The peripheral region AN is provided therein with a gate driving circuit (e.g., Gate on Array (GOA)), control signal lines (e.g., clock signal lines, power supply voltage signal lines, and the like) and a bonding driver chip (e.g., source driver integrated circuit (IC) or source driver chip). Functions of the peripheral region AN include but are not limited to this.

For example, as shown in FIG. 2, the peripheral region AN includes a bonding region BB, and the bonding region BB is located on a side of the display region AA in the second direction Y. The bonding region BB is adjacent to a border of the display region AA. For example, the bonding region BB is adjacent to a lower border of the display region AA. In the bonding region BB, the display substrate 100 is connected to external driver(s).

For example, the bonding region BB is configured such that signal lines (e.g., data lines DL, first voltage signal lines VSS, and reference voltage signal lines VRef1) extend to the bonding region BB to be bonded to a driver circuit board (e.g., the circuit board 200) or a driver chip. That is, the bonding region BB is located on a side of the display substrate 100 for bonding the driver circuit board or the driver chip.

In some embodiments, as shown in FIG. 2, the display substrate 100 includes a plurality of pixel circuits 10 and a plurality of light-emitting devices 20. The plurality of pixel circuits 10 are arranged in a plurality of rows and a plurality of columns. A row of pixel circuits 10 is arranged in the first direction X, and each row of pixel circuits 10 includes multiple pixel circuits 10 arranged at intervals in the first direction X. A column of pixel circuits 10 is arranged in the second direction Y, and each column of pixel circuits 10 includes multiple pixel circuits 10 arranged at intervals in the second direction Y. That is, the first direction X is a row direction in which the plurality of sub-pixels P are arranged, and the second direction Y is a column direction in which the plurality of sub-pixels P are arranged. The first direction X and the second direction Y intersect.

For example, the first direction X is perpendicular to the second direction Y.

For example, each pixel circuit 10 is connected to a light-emitting device 20, and the pixel circuit 10 is configured to drive the light-emitting device 20 connected thereto to emit light.

For example, the light-emitting devices 20 include, but are not limited to, organic light-emitting diodes (OLEDs), mini light-emitting diodes (mini LEDs), micro light-emitting diode (micro LEDs), or the like.

In some embodiments, as shown in FIGS. 2 and 3, the display substrate 100 further includes: a plurality of data lines DL, first fan-out line(s) FIP1 and second fan-out line(s) FIP2. The data lines DL extend in the second direction Y. A column of pixel circuits 10 is electrically connected to a data line DL. At least one of the plurality of data lines DL is a setting data line DL1, and the second fan-out line FIP2 is closer to a center line, along the second direction Y, of the bonding region BB than the setting data line DL1.

The first fan-out line FIP1 and the second fan-out line FIP2 are disposed in the display region AA. The first fan-out line FIP1 extends in the first direction X, and the second fan-out line FIP2 extends in the second direction Y. An end of the first fan-out line FIP1 is electrically connected to a setting data line DL1, and another end of the first fan-out line FIP1 is electrically connected to the second fan-out line FIP2.

As shown in FIG. 2, at least one of the plurality of pixels P is a setting pixel PP, and a single setting pixel PP corresponds to at least one second fan-out line FIP2. The second fan-out line(s) FIP2 pass through a region between pixel circuits 10 of two adjacent sub-pixels P(x) in the corresponding setting pixel PP or pass through an outer side of an outer pixel circuit 10 of the corresponding setting pixel PP, and extend to the bonding region BB.

In some embodiments, as shown in FIG. 2, the setting data line DL1 is farther away from the center line, along the second direction Y, of the bonding region BB than remaining data lines DL among the plurality of data lines DL. The entire setting data line DL1 is located in the display region AA, and ends of the remaining data lines DL extend to the bonding region BB.

For example, as shown in FIG. 2, the data lines DL may include first data line(s) DL1 and second data line(s) DL2. The first data line DL1 is a setting data line DL1. The setting data line DL1 is located within the display region AA and does not extend to the bonding region BB. The second fan-out line FIP2 and the second data line DL2 extend to the bonding region BB. The setting data line DL1, the first fan-out line FIP1, and the second fan-out line FIP2 are connected in sequence. Each first fan-out line FIP1 is electrically connected to one setting data line DL1 and one second fan-out line FIP2.

In other words, the second data line DL2 directly extends to the bonding region BB, and the setting data line DL1 is a data line DL in the display substrate 100 that needs to be led out to the bonding region BB via the first fan-out line FIP1 and the second fan-out line FIP2 in sequence. This arrangement manner may be called Fanout In Pixel (FIP).

As shown in FIG. 2, a width of a border of the display substrate 100 for bonding the driver, for example, a width of a portion of the peripheral region AN located below the display region AA shown in FIG. 2, is d1; a size of the bonding region BB in the second direction Y is d2; and d1 is greater than or equal to d2 (d1≥d2). In this way, a size d1 of a portion of the peripheral region AN where the bonding region BB is arranged may be reduced, which is conducive to realizing a narrow border of the display apparatus 1000.

Since the second fan-out line FIP2 is arranged in the pixel P or arranged between adjacent pixels P and the setting data line DL1 is led out to the bonding region BB via the first fan-out line FIP1 and the second fan-out line FIP2, it is possible to increase the number of signal lines for transmitting data signals in the display region AA and increase the density of the signal lines for transmitting data signals, and in turn reduce the overall resistance of the signal lines for transmitting data signals, which is conducive to realizing stability and reliability of transmission of data signals. In addition, the added second fan-out line FIP2 is interposed between adjacent pixel circuits 10, thereby ensuring the uniformity of the film layer of the display substrate 100, and in turn ensuring the display effect of the display substrate 100.

For example, as shown in FIG. 2, the setting pixel PP includes three sub-pixels P(x) arranged in sequence in the first direction X. For example, the three sub-pixels P(x) are a first sub-pixel PP(1), a second sub-pixel PP(2) and a third sub-pixel PP(3) from the left side to the right side in FIG. 2.

In some examples, as shown in FIG. 2, a single setting pixel PP in the display substrate 100 corresponds to a single second fan-out line FIP2, and the second fan-out line FIP2 passes through an outer side of an outer pixel circuit 10 of the corresponding setting pixel PP, and extends to the bonding region BB.

For example, the second fan-out line FIP2 passes through a side of a pixel circuit 10 of the first sub-pixel PP(1) away from a pixel circuit 10 of the second sub-pixel PP(2), and extends to the bonding region BB.

For another example, the second fan-out line FIP2 passes through a side of a pixel circuit 10 of the third sub-pixel PP(3) away from the pixel circuit 10 of the second sub-pixel PP(2), and extends to the bonding region BB.

In some other examples, as shown in FIG. 3, a single setting pixel PP in the display substrate 100 corresponds to a single second fan-out line FIP2, and the second fan-out line FIP2 passes through a region between pixel circuits 10 of two adjacent sub-pixels P(x) in the corresponding setting pixel PP and extends to the bonding region BB.

For example, the second fan-out line FIP2 passes through a region between the pixel circuit 10 of the first sub-pixel PP(1) and the pixel circuit 10 of the second sub-pixel PP(2), and extends to the bonding region BB. Alternatively, as shown in FIG. 3, the second fan-out line FIP2 passes through a region between the pixel circuit 10 of the second sub-pixel PP(2) and the pixel circuit 10 of the third sub-pixel PP(3), and extends to the bonding region BB.

In yet some other examples, a single setting pixel PP in the display substrate 100 corresponds to two second fan-out lines FIP2, and the second fan-out line FIP2 passes through a region between pixel circuits 10 of two adjacent sub-pixels P(x) in the corresponding setting pixel PP and extends to the bonding region BB.

For example, one second fan-out line FIP2 passes through the region between the pixel circuit 10 of the first sub-pixel PP(1) and the pixel circuit 10 of the second sub-pixel PP(2), and extends to the bonding region BB; and another second fan-out line FIP2 passes through the region between the pixel circuit 10 of the second sub-pixel PP(2) and the pixel circuit 10 of the third sub-pixel PP(3), and extends to the bonding region BB.

In yet some other examples, a single setting pixel PP in the display substrate 100 corresponds to three second fan-out lines FIP2, and the second fan-out line FIP2 passes through a region between pixel circuits 10 of two adjacent sub-pixels P(x) in the corresponding setting pixel PP and extends to the bonding region BB.

For example, one second fan-out line FIP2 passes through the region between the pixel circuit 10 of the first sub-pixel PP(1) and the pixel circuit 10 of the second sub-pixel PP(2), and extends to the bonding region BB; another second fan-out line FIP2 passes through the region between the pixel circuit 10 of the second sub-pixel PP(2) and the pixel circuit 10 of the third sub-pixel PP(3), and extends to the bonding region BB; and yet another second fan-out line FIP2 passes through an outer side of an outer pixel circuit 10 of the corresponding setting pixel PP, and extends to the bonding region BB.

In yet some other examples, a single setting pixel PP in the display substrate 100 corresponds to four second fan-out lines FIP2. In the first direction X, a first second fan-out line FIP2 passes through a side of the pixel circuit 10 of the first sub-pixel PP(1) away from the second sub-pixel PP(2) and extends to the bonding region BB, a second second fan-out line FIP2 passes through the region between the pixel circuit 10 of the first sub-pixel PP(1) and the pixel circuit 10 of the second sub-pixel PP(2) and extends to the bonding region BB, a third second fan-out line FIP2 passes through the region between the pixel circuit 10 of the second sub-pixel PP(2) and the pixel circuit 10 of the third sub-pixel PP(3) and extends to the bonding region BB, and a fourth second fan-out line FIP2 passes through a side of the pixel circuit 10 of the third sub-pixel PP(3) away from the second sub-pixel PP(2) and extends to the bonding region BB.

It will be understood that in a case where the setting pixel PP includes three sub-pixels P(x) and each of two sides of the setting pixel PP in the first direction X is adjacent to another pixel P, one or two second fan-out lines FIP2 may be provided between two adjacent pixels P (one of which is the setting pixel PP). In a case where two adjacent pixels P are both setting pixels PP and the number of second fan-out lines FIP2 corresponding to a single setting pixel PP is less than or equal to the number of sub-pixels P(x) included in the setting pixel PP, when a second fan-out line FIP2 corresponding to a first setting pixel PP is located between the two setting pixels PP, any one of second fan-out lines FIP2 corresponding to a second setting pixel PP may be located between the two setting pixels PP, or located between sub-pixels P(x) in the second setting pixel PP, or located on a side of the second setting pixel PP away from the first setting pixel PP.

Since the first fan-out line FIP and the second fan-out line FIP2 are provided, a data line DL corresponding to at least a part of the plurality of sub-pixels P(x) included in the setting pixel PP is led out from the display region AA to the bonding region BB via the second fan-out line FIP2 instead of being led out from the peripheral region AN to the bonding region BB, which reduces a wiring area of data lines DL in the peripheral region AN and reduce the size d1, in the second direction Y, of the portion of the peripheral region AN where the bonding region BB is arranged, and in turn realize a narrow border of the display apparatus 1000.

It will be noted that an outer side of an outer pixel circuit 10 of the setting pixel PP means a region between the setting pixel PP and another pixel P adjacent to the setting pixel PP, and the another pixel P may also be a setting pixel PP.

The above description is only an exemplary description and is not intended to limit the present disclosure. Each setting pixel PP may also include four, five or more sub-pixels P(x). In some examples, the number of second fan-out lines FIP2 corresponding to each setting pixel PP is less than or equal to the number of sub-pixels P(x) included in each setting pixel PP; and the second fan-out lines FIP2 pass through a region between pixel circuits 10 of two adjacent sub-pixels P(x) in the corresponding setting pixel PP or pass through an outer side of an outer pixel circuit 10 of the corresponding setting pixel PP, and extend to the bonding region BB. In some other examples, the number of second fan-out lines FIP2 corresponding to each setting pixel PP is greater than the number of sub-pixels P(x) included in each setting pixel PP; and a part of the second fan-out lines FIP2 passes through a region between pixel circuits 10 of two adjacent sub-pixels P(x) in the corresponding setting pixel PP and another part of the second fan-out lines FIP2 passes through an outer side of an outer pixel circuit 10 of the corresponding setting pixel PP, and all extend to the bonding region BB.

For example, as shown in FIG. 2, the data lines DL need to extend to the bonding region BB and are bonded and connected to a driver (e.g., a driver circuit board or a driver chip) in the bonding region BB. The driver transmits data signals to the data lines DL, so that the pixel circuits 10 can drive the light-emitting devices 20 to emit light.

As shown in FIG. 2, in the first direction X, a size of the bonding region BB is, for example, less than a size of the display region AA; and in the second direction Y, the bonding region BB may be arranged opposite to a middle region of the display region AA. Data lines DL located at two borders of the display region AA in the first direction X are setting data lines DL1 (first data lines DL1), and data lines DL located in the middle region of the display region AA in the first direction X are second data lines DL2.

In some embodiments, the display substrate does not include the first fan-out line FIP1 and the second fan-out line FIP2, and an end of the setting data line DL1 close to the bonding region BB extends to the peripheral region AN and converges on the bonding region BB. Referring to FIG. 2, in the display substrate 100, the size, in the first direction X, of the bonding region BB is less than the size, in the first direction X, of the display region AA. In this case, a portion of the setting data line DL1 located in the peripheral region AN and extending into the bonding region BB will occupy space in the peripheral region AN. Therefore, the portion of the peripheral region AN where the bonding region BB is arranged has a large size in the second direction Y, and the border of the display substrate 100 for bonding the driver has a large width.

In some other embodiments, as shown in FIG. 2, in the second direction Y, the second data lines DL2 are arranged opposite to the bonding region BB; and setting data lines DL1 are located on two sides of the second data line DL2 in the first direction X. In this case, first data lines DL1 located on two sides, in the first direction X, of the bonding region BB are led out to the bonding region BB via first fan-out lines FIP1 and second fan-out lines FIP2, and the second data lines DL2 arranged opposite to the bonding region BB are directly led out to the bonding region BB.

Based on the design shown in FIG. 2, the plurality of data lines DL (setting data line(s) DL1 and second data line(s) DL2) are led out from the display region AA to the bonding region BB. The data lines DL do not occupy the space in the peripheral region AN, which is conducive to reducing the size d2, in the second direction Y, of the portion of the peripheral region AN where the bonding region BB is arranged, and in turn realizing a narrow border of the display apparatus 1000.

It will be noted that there may be a plurality of bonding regions BB in the display substrate 100. For example, in a large-sized display apparatus (e.g. a TV or a computer), the display substrate 100 may include a plurality of bonding regions BB, a data line DL arranged opposite to a bonding region BB in the second direction Y may be considered as a second data line DL2, and remaining data line(s) DL may be considered as first data line(s) DL1 (setting data line(s) DL1). Of course, the manner of distinguishing the first data line DL1 and the second data line DL2 is not limited thereto, and the first data line DL1 and the second data line DL2 may be arranged in different regions according to needs.

In some embodiments, as shown in FIG. 3, the display substrate 100 further includes first voltage signal lines VSS extending in the second direction Y. A single setting pixel PP corresponds to at least one first voltage signal line VSS. The first voltage signal line VSS passes through a region between pixel circuits 10 of two adjacent sub-pixels P(x) in the corresponding setting pixel PP, or passes through an outer side of an outer pixel circuit 10 of the corresponding setting pixel PP.

The setting pixel PP including a first sub-pixel PP(1), a second sub-pixel PP(2), and a third sub-pixel PP(3) arranged in sequence in the first direction X is taken as an example for introduction.

In some examples, in the display substrate 100, a single setting pixel PP corresponds to a single first voltage signal line VSS, and the first voltage signal line VSS passes through an outer side of an outer pixel circuit 10 of the corresponding setting pixel PP.

For example, the first voltage signal line VSS passes through the side of the pixel circuit 10 of the first sub-pixel PP(1) away from the pixel circuit 10 of the second sub-pixel PP(2).

For another example, the first voltage signal line VSS passes through the side of the pixel circuit 10 of the third sub-pixel PP(3) away from the pixel circuit 10 of the second sub-pixel PP(2).

In some other examples, as shown in FIG. 3, in the display substrate 100, a single setting pixel PP corresponds to a single first voltage signal line VSS, and the first voltage signal line VSS passes through a region between pixel circuits 10 of two adjacent sub-pixels P(x) in the corresponding setting pixel PP.

For example, as shown in FIG. 3, the first voltage signal line VSS passes through the region between the pixel circuit 10 of the first sub-pixel PP(1) and the pixel circuit 10 of the second sub-pixel PP(2); alternatively, the first voltage signal line VSS passes through the region between the pixel circuit 10 of the second sub-pixel PP(2) and the pixel circuit 10 of the third sub-pixel PP(3).

In yet some other examples, in the display substrate 100, a single setting pixel PP corresponds to two first voltage signal lines VSS, and the first voltage signal line VSS passes through a region between pixel circuits 10 of two adjacent sub-pixels P(x) in the corresponding setting pixel PP.

For example, one first voltage signal line VSS passes through the region between the pixel circuit 10 of the first sub-pixel PP(1) and the pixel circuit 10 of the second sub-pixel PP(2), and another first voltage signal line VSS passes through the region between the pixel circuit 10 of the second sub-pixel PP(2) and the pixel circuit 10 of the third sub-pixel PP(3).

In yet some other examples, in the display substrate 100, a single setting pixel PP corresponds to three first voltage signal lines VSS, and the first voltage signal line VSS passes through a region between pixel circuits 10 of two adjacent sub-pixels P(x) in the corresponding setting pixel PP.

For example, one first voltage signal line VSS passes through the region between the pixel circuit 10 of the first sub-pixel PP(1) and the pixel circuit 10 of the second sub-pixel PP(2); another first voltage signal line VSS passes through the region between the pixel circuit 10 of the second sub-pixel PP(2) and the pixel circuit 10 of the third sub-pixel PP(3); and yet another first voltage signal line VSS passes through an outer side of an outer pixel circuit 10 of the corresponding setting pixel PP.

In yet some other examples, in the display substrate 100, a single setting pixel PP corresponds to four first voltage signal lines VSS. In the first direction X, a first first voltage signal line VSS passes through a side of the pixel circuit 10 of the first sub-pixel PP(1) away from the second sub-pixel PP(2), a second first voltage signal line VSS passes through the region between the pixel circuit 10 of the first sub-pixel PP(1) and the pixel circuit 10 of the second sub-pixel PP(2), a third first voltage signal line VSS passes through the region between the pixel circuit 10 of the second sub-pixel PP(2) and the pixel circuit 10 of the third sub-pixel PP(3), and a fourth first voltage signal line VSS passes through a side of the pixel circuit 10 of the third sub-pixel PP(3) away from the second sub-pixel PP(2).

It will be understood that, in a case where the setting pixel PP includes three sub-pixels P(x) and each of two sides of the setting pixel PP in the first direction X is adjacent to another pixel P, one or two first voltage signal lines VSS may be provided between two adjacent pixels P (one of which is the setting pixel PP). In a case where two adjacent pixels P are both setting pixels PP and the number of first voltage signal lines VSS corresponding to a setting pixel PP is less than or equal to the number of sub-pixels P(x) included in the setting pixel PP, when a first voltage signal line VSS corresponding to a first setting pixel PP is located between the two setting pixels PP, any one of first voltage signal lines VSS corresponding to a second setting pixel PP may be located between the two setting pixels PP, or located between sub-pixels P(x) in the second setting pixel PP, or located on a side of the second setting pixel PP away from the first setting pixel PP.

Since the first voltage signal line(s) VSS are arranged in the setting pixel PP or arranged between the setting pixel PP and an adjacent pixel P (which may also be another setting pixel PP), the number of the first voltage signal lines VSS arranged in the display region AA is increased, and the density of the first voltage signal lines VSS in the display region AA is increased. Thus, the overall resistance of the first voltage signal lines VSS is reduced, which is conducive to reducing the voltage drop of the first voltage signal lines VSS and ensuring the stability and reliability of transmission of first voltage signals.

In some embodiments, as shown in FIG. 3, among at least one second fan-out line FIP2 corresponding to the setting pixel PP and at least one first voltage signal line VSS corresponding to the setting pixel PP, one second fan-out line FIP2 passes through a region between pixel circuits 10 of a pair of adjacent sub-pixels P(x), and one first voltage signal line VSS passes through a region between pixel circuits 10 of another pair of adjacent sub-pixels P(x).

Since the second fan-out line FIP2 is arranged between pixel circuits 10 of adjacent sub-pixels P(x) in the setting pixel PP and the first voltage signal line VSS is arranged between pixel circuits 10 of adjacent sub-pixels P(x) in the setting pixel PP, the density of signal lines for transmitting first voltage signals and the density of signal lines for transmitting data signals within the display region AA are increased. Therefore, the overall resistance of the first voltage signal lines VSS and the overall resistance of the data lines DL are reduced, which is conducive to reducing the voltage drop of the first voltage signal lines VSS and the voltage drop of the data lines DL, and ensuring the stability and reliability of transmission of the first voltage signals and the data signals.

For example, as shown in FIG. 3, each pixel P includes three sub-pixels P(x). The setting pixel PP corresponds to a single second fan-out line FIP2 and a single first voltage signal line VSS. The second fan-out line FIP2 passes through a region between pixel circuits 10 of a pair of adjacent sub-pixels P(x) among the three sub-pixels P(x), and the first voltage signal line VSS passes through a region between pixel circuits 10 of another pair of adjacent sub-pixels P(x) among the three sub-pixels P(x).

For example, as shown in FIG. 3, the setting pixel PP includes a first sub-pixel P(1), a second sub-pixel P(2) and a third sub-pixel P(3) arranged in sequence in the first direction X. The first voltage signal line VSS passes through the region between pixel circuits 10 of the first sub-pixel P(1) and the second sub-pixel P(2), and the second fan-out line FIP2 passes between pixel circuits 10 of the second sub-pixel P(2) and the third sub-pixel P(3) and extends to the bonding region BB.

It will be noted that in the case where each pixel P includes three sub-pixels P(x), it may also be that the second fan-out line FIP2 passes through the region between the pixel circuits 10 of the first sub-pixel P(1) and the second sub-pixel P(2) and extends to the bonding region BB, and the first voltage signal line VSS passes between pixel circuits 10 of the second sub-pixel P(2) and the third sub-pixel P(3).

In some embodiments, as shown in FIG. 4, among the second fan-out line(s) FIP2 and the first voltage signal line(s) VSS corresponding to the setting pixel PP, one first voltage signal line VSS and one second fan-out line FIP2 pass through a region between pixel circuits 10 of the same pair of adjacent sub-pixels P(x).

For example, the pixel circuit 10 includes a plurality of transistors (thin film transistors (TFTs)), at least one capacitor, and at least one connection node. Part of the connection nodes (e.g., a fifth node N5 shown in FIG. 11) plays a key role in the operation of the pixel circuit 10. As for the specific structure of the pixel circuit 10, reference is made to the following description, which is not introduced here.

Since one first voltage signal line VSS and one second fan-out line FIP2 corresponding to the setting pixel PP pass through the region between the pixel circuits 10 of the same pair of adjacent sub-pixels P(x), the wiring density of the signal lines for transmitting first voltage signals in the display region AA is increased, the resistance of the signal lines for transmitting the first voltage signals in the display region AA is reduced, and the voltage drop of the first voltage signals is reduced.

In addition, the first voltage signal lines VSS, as constant voltage signal lines, have a signal shielding effect, thereby preventing the data signal transmitted by the second fan-out line FIP2 passing through a region between pixel circuits 10 of adjacent sub-pixels P(x) from generating signal crosstalk with nodes in the pixel circuit 10, and in turn ensuring the normal operation of the pixel circuit 10.

For example, as shown in FIG. 4, the pixel P includes three sub-pixels P(x). The setting pixel PP corresponds to a single second fan-out line FIP2 and a single first voltage signal line VSS. The second fan-out line FIP2 and the first voltage signal line VSS pass through a region between pixel circuits 10 of the same pair of adjacent sub-pixels P(x) among the three sub-pixels P(x).

For example, as shown in FIG. 4, the setting pixel PP includes a first sub-pixel P(1), a second sub-pixel P(2) and a third sub-pixel P(3) arranged in sequence in the first direction X. The first voltage signal line VSS and the second fan-out line FIP2 both pass through the region between the pixel circuits 10 of the first sub-pixel P(1) and the second sub-pixel P(2).

It will be noted that in the case where each pixel P includes three sub-pixels P(x), the first voltage signal line VSS and the second fan-out line FIP2 may pass through the region between the pixel circuits 10 of the second sub-pixel P(2) and the third sub-pixel P(3).

In some embodiments, as shown in FIG. 6, the second fan-out line FIP2 is provided therein with a second disconnected opening DK2, and the second disconnected opening DK2 divides the second fan-out line FIP2 into an effective portion FIP21 and a redundant portion FIP22. An end of the effective portion FIP21 of the second fan-out line FIP2 is electrically connected to the first fan-out line FIP1, and another end of the effective portion FIP21 extends to the bonding region BB.

For example, as shown in FIG. 6, the second disconnected opening DK2 divides the second fan-out line FIP2 into an effective portion FIP21 and a redundant portion FIP22 that are electrically insulated from each other. Referring to FIGS. 2 and 5, an end (e.g., a lower end shown in FIG. 2) of the effective portion FIP21 of the second fan-out line FIP2 extends to the bonding region BB, and another end of the effective portion FIP21 is connected to the first fan-out line FIP1. An end, away from the bonding region BB, of the effective portion FIP21 of the second fan-out line FIP2 is electrically insulated from the redundant portion FIP22 of the second fan-out line FIP2. Therefore, the first fan-out line FIP1 is electrically connected to the effective portion FIP21 of the second fan-out line FIP2, and extends to the bonding region BB via the effective portion FIP21 of the second fan-out line FIP2.

Since the second disconnected opening DK2 divides the second fan-out line FIP2 into the effective portion FIP21 and the redundant portion FIP22 that are electrically insulated from each other, the data signal is output from the driver bonded in the bonding region BB, sequentially passes through the effective portion FIP21 of the second fan-out line FIP2, the first fan-out line FIP1 and the setting data line DL1, and then is transmitted to corresponding sub-pixels P(x). In this way, the transmission path of the data signal does not include the redundant portion FIP22 of the second fan-out line FIP2, which is conducive to shortening the transmission path of the data signal on the second fan-out line FIP2. Therefore, it reduces the voltage drop of the data signal during the transmission on the second fan-out line FIP2, prevents signal distortion caused by the voltage drop, and ensures the accuracy of data signal transmission.

It will be noted that the redundant portion FIP22 of the second fan-out line FIP2 may be configured to transmit no signals, or configured to transmit a signal except for the data signal.

In some embodiments, as shown in FIGS. 8 and 10, the display substrate 100 further includes a first connection portion LJ1. The first voltage signal line VSS and the redundant portion FIP22 of the second fan-out line FIP2 are electrically connected through the first connection portion LJ1. The redundant portion FIP22 of the second fan-out line FIP2 is configured to transmit a first voltage signal.

Since the first connection portion LJ1 connects the redundant portion FIP22 of the second fan-out line FIP2 to the first voltage signal line VSS, the wiring area of the first voltage signal lines VSS in the display region AA is increased. Thus, the density of the first voltage signal lines VSS in the display region AA is increased, which is conducive to reducing the resistance of the first voltage signal lines VSS, and in turn reducing the voltage drop of the first voltage signal lines VSS.

In some embodiments, as shown in FIGS. 4, 8 and 10, the first voltage signal line VSS and the second fan-out line FIP2 that pass through a region between the pixel circuits 10 of the same pair of adjacent sub-pixels P(x) are arranged adjacent to each other, and the first voltage signal line VSS, the second fan-out line FIP2 and the first connection portion LJ1 are arranged in the same layer and constitute a one-piece structure.

For example, during the process of manufacturing the display substrate 100, a conductive structure layer is first formed by a sputtering process, and then the conductive structure layer is patterned by an etching process, so as to form the first voltage signal line VSS, the first connection portion LJ1 and the second fan-out line FIP2 that are connected. In this way, the first voltage signal line VSS, the second fan-out line FIP2 and the first connection portion LJ1 are simultaneously formed in the same manufacturing step. In addition, the first voltage signal line VSS, the first connection portion LJ1 and the second fan-out line FIP2 are connected to each other to form a one-piece structure, and there is no need to provide other structures for connecting the first voltage signal line VSS, the first connection portion LJ1 and the second fan-out line FIP2. Therefore, when the first connection portion LJ1 and the second fan-out line FIP2 are added, there is no need to increase the steps of the manufacturing process of the display substrate 100, which is conducive to reducing production costs.

It will be noted that the first voltage signal line VSS, the first connection portion LJ1 and the second fan-out line FIP2 may also be formed by other methods. This is only an exemplary description and is not intended to limit the present disclosure.

In some embodiments, as shown in FIG. 6, the first fan-out line FIP1 is provided therein with a first disconnected opening DK1, and the first disconnected opening DK1 divides the first fan-out line FIP1 into an effective portion FIP11 and a redundant portion FIP12. An end of the effective portion 11 of the first fan-out line FIP1 is electrically connected to the setting data line DL1, and another end of the effective portion 11 is electrically connected to the effective portion FIP21 of the second fan-out line FIP2.

For example, as shown in FIG. 6, the first disconnected opening DK1 divides the first fan-out line FIP1 into an effective portion FIP11 and a redundant portion FIP12 that are electrically insulated from each other. Referring to FIGS. 2 and 5, an end (e.g., a lower end shown in FIG. 2) of the effective portion FIP11 of the first fan-out line FIP1 extends to the bonding region BB, and another end of the effective portion FIP11 is connected to the second fan-out line FIP2. An end, away from the bonding region BB, of the effective portion FIP11 of the first fan-out line FIP1 is electrically insulated from the redundant portion FIP12 of the first fan-out line FIP1. That is, the effective portion FIP11 of the first fan-out line FIP1 is electrically connected to the effective portion FIP21 of the second fan-out line FIP2, and extends to the bonding region BB via the effective portion FIP21 of the second fan-out line FIP2.

Since the first disconnected opening DK1 divides the first fan-out line FIP1 into the effective portion FIP11 and the redundant portion FIP12 that are electrically insulated from each other, the data signal is output from the driver bonded in the bonding region BB, sequentially passes through the effective portion FIP21 of the second fan-out line FIP2, the effective portion FIP11 of the first fan-out line FIP1 and the setting data line DL1, and then is transmitted to corresponding sub-pixels P(x). In this way, the transmission path of the data signal does not include the redundant portion FIP22 of the second fan-out line FIP2 and the redundant portion FIP12 of the first fan-out line FIP1, which is conducive to shortening the transmission path of the data signal on the first fan-out line FIP1 and the second fan-out line FIP2. Therefore, it reduces the voltage drop of the data signal during the transmission on the first fan-out line FIP1 and the second fan-out line FIP2, prevents signal distortion caused by the voltage drop, and ensures the accuracy of data signal transmission.

In some embodiments, as shown in FIGS. 8 and 9, the display panel 100 further includes a second connection portion LJ2. In a thickness direction of the display substrate 100, a via hole K is provided between the second connection portion LJ2 and the redundant portion FIP22 of the second fan-out line FIP2. An end of the second connection portion LJ2 is electrically connected to the redundant portion FIP12 of the first fan-out line FIP1, and another end of the second connection portion LJ2 is electrically connected to the redundant portion FIP22 of the second fan-out line FIP2 through the via hole K.

For example, the first fan-out line FIP1 and the second fan-out line FIP2 are located in different film layers. That is, in the thickness direction of the display substrate 100, a film layer where the first fan-out line FIP1 is located and a film layer where the second fan-out line FIP2 is located are at different distances from a substrate 1 of the display substrate 100.

There may also be an insulating separation layer (such as a planarization layer 6) between the first fan-out line FIP1 and the second fan-out line FIP2. The first fan-out line FIP1 and the second fan-out line FIP2 are electrically insulated. A portion of the planarization layer 6 between ends, close to each other, of the redundant portion FIP22 of the second fan-out line FIP2 and the second connection portion LJ2 is provided with a via hole K, so that an end of the second connection portion LJ2 is connected to the redundant portion FIP22 of the second fan-out line FIP2 through the via hole K. In this way, the redundant portion FIP12 of the first fan-out line FIP1 is connected to the redundant portion FIP22 of the second fan-out line FIP2 through the second connection portion LJ2, so that the wiring area of the first voltage signal lines VSS in the display region AA is increased, and the density of the first voltage signal lines VSS in the display region AA is increased. The redundant portion FIP12 of the first fan-out line FIP1 and the redundant portion FIP22 of the second fan-out line FIP2 are arranged in parallel, which is conducive to reducing the resistance of the first voltage signal lines VSS, and in turn reducing the voltage drop of the first voltage signal lines VSS.

In some embodiments, as shown in FIG. 9, the second connection portion LJ2 and the redundant portion FIP12 of the first fan-out line FIP1 are arranged in the same layer and constitute a one-piece structure.

For example, during the process of manufacturing the display substrate 100, a conductive structure layer is first formed by a sputtering process, and then the conductive structure layer is patterned by an etching process, so as to form the redundant portion FIP12 of the first fan-out line FIP1 and the second connection portion LJ2 that are connected. In this way, the redundant portion FIP12 of the first fan-out line FIP1 and the second connection portion LJ2 are simultaneously formed in the same manufacturing step. In addition, the second connection portion LJ2 and the redundant portion FIP12 of the first fan-out line FIP1 are connected to each other to form a one-piece structure, and there is no need to provide other structures for connecting the second connection portion LJ2 and the redundant portion FIP12 of the first fan-out line FIP1. Therefore, when the redundant portion FIP12 of the first fan-out line FIP1 and the second connection portion LJ2 are added, there is no need to increase the steps of the manufacturing process of the display substrate 100, which is conducive to reducing production costs.

It will be noted that the redundant portion FIP12 of the first fan-out line FIP1 and the second connection portion LJ2 may also be formed by other methods. This is only an exemplary description and is not intended to limit the present disclosure.

In some embodiments, as shown in FIGS. 3 and 4, the display substrate 100 further includes a plurality of reference voltage signal lines VRef1. The reference voltage signal lines VRef1 extends in the second direction Y. A column of pixel circuits 10 is electrically connected to a reference voltage signal line VRef1. Among two adjacent columns of pixel circuits 10, a reference voltage signal line VRef1 connected to one column of pixel circuits 10 and a data line DL connected to another column of pixel circuits 10 are arranged close to each other. The second fan-out line FIP2 is arranged between the reference voltage signal line VRef1 and the data line DL that are arranged close to each other.

For example, as shown in FIGS. 3 and 4, each column of pixel circuits 10 is electrically connected to a data line DL and a reference voltage signal line VRef1. A column of pixel circuits 10 extends in the second direction Y, and the data line DL and the reference voltage signal line VRef1 that are connected to the column of pixel circuits 10 are respectively located on two sides of the column of pixel circuits 10 in the first direction X. A second fan-out line FIP2 is arranged between two adjacent columns of pixel circuits 10 to lead out a setting data line DL1 from the display region AA to the bonding region BB In some embodiments, as shown in FIGS. 3 and 4, a first voltage signal line VSS in the display substrate 100 is arranged between the reference voltage signal line VRef1 and the data line DL that are arranged close to each other.

For example, as shown in FIGS. 3 and 4, the data line DL and the reference voltage signal line VRef1 connected to a column of pixel circuits 10 are respectively located on two sides of the column of pixel circuits 10 in the first direction X. A first voltage signal line VSS is arranged between two adjacent columns of pixel circuits 10, so that the density of the first voltage signal lines VSS in the display region AA is increased. Thus, the overall resistance of the first voltage signal lines VSS is reduced, which is conducive to reducing the voltage drop of the first voltage signal lines VSS and ensuring the stability and reliability of transmission of first voltage signals.

In some embodiments, as shown in FIG. 11, the pixel circuit 10 includes a plurality of transistors (TFTs) and at least one capacitor.

For example, the pixel circuit 10 may be a “3T1C” circuit, a “7T1C” circuit, a “8T1C” circuit, a “9T2C” circuit, or the like. Here, “T” represents a TFT, a number before “T” represents the number of TFTs, “C” represents a capacitor, and a number before “C” represents the number of capacitors. In the embodiments of the present disclosure, the pixel circuit 10 being a “9T2C” circuit is taken as an example for illustration. However, the embodiments of the present disclosure are not limited thereto, and any other pixel circuit 10 may also be considered as long as the same technical concept is applied.

For example, as shown in FIG. 11 which is an equivalent circuit diagram of a pixel circuit 10 of a 9T2C mode, the pixel circuit 10 may include a first transistor T1, a second transistor T2, a third transistor T3, a fourth transistor T4, a fifth transistor T5, a sixth transistor T6, a seventh transistor T7, an eighth transistor T8, a ninth transistor T9, a first capacitor C1 and a second capacitor C2. Signal lines (for example, a data signal line DL, a first enable signal line EM1, a second enable signal line EM2, an initialization signal line Vinit, a first voltage signal line VSS, a second voltage signal line VDD, and the like) are electrically connected to the pixel circuit 10.

For example, as shown in FIG. 11, each pixel circuit 10 is connected to three gate signal lines GL, which are a first gate signal line GL1, a second gate signal line GL2, and a third gate signal line GL3.

A gate of the first transistor T1 is electrically connected to the third gate signal line GL3, a first electrode of the first transistor T1 is electrically connected to a first initialization signal line Vinit1, and a second electrode of the first transistor T1 is electrically connected to a.

A gate of the second transistor T2 is electrically connected to the second gate signal line GL2, a first electrode of the second transistor T2 is electrically connected to the first node N1, and a second electrode of the second transistor T2 is electrically connected to a third node N3.

A gate of the third transistor T3 is electrically connected to the first node N1, a first electrode of the third transistor T3 is electrically connected to a second node N2, and a second electrode of the third transistor T3 is electrically connected to the third node N3.

A gate of the fourth transistor T4 is electrically connected to the first gate signal line GL1, a first electrode of the fourth transistor T4 is electrically connected to the data line DL, and a second electrode of the fourth transistor T4 is electrically connected to a fifth node N5.

A gate of the fifth transistor T5 is electrically connected to the first enable signal line EM1, a first electrode of the fifth transistor T5 is electrically connected to the second voltage signal line VDD, and a second electrode of the fifth transistor T5 is electrically connected to the second node N2.

A gate of the sixth transistor T6 is electrically connected to the second enable signal line EM2, and a first electrode of the sixth transistor T6 is electrically connected to the third node N3, and a second electrode of the sixth transistor T6 is electrically connected to a fourth node N4.

A gate of the seventh transistor T7 is electrically connected to a scan signal line Scan, a first electrode of the seventh transistor T7 is electrically connected to a second initialization signal line Vinit2, and a second electrode of the seventh transistor T7 is electrically connected to the fourth node N4.

A gate of the eighth transistor T8 is electrically connected to the scan signal line Scan, a first electrode of the eighth transistor T8 is electrically connected to a second reference voltage signal line VRef2, and a second electrode of the eighth transistor T8 is electrically connected to the second node N2.

A gate of the ninth transistor T9 is electrically connected to the second gate signal line GL2, a first electrode of the ninth transistor T9 is electrically connected to the first reference voltage signal line VRef1, and a second electrode of the ninth transistor T9 is electrically connected to the fifth node N5.

A first plate C11 of the first capacitor C1 is electrically connected to the fifth node N5, and a second plate C12 of the first capacitor C1 is electrically connected to the first node N1.

A first plate C21 of the second capacitor C2 is electrically connected to the fifth node N5, and a second plate C22 of the second capacitor C2 is electrically connected to the second voltage signal line VDD.

Since the fifth node N5 is electrically connected to the first capacitor C1 and the second capacitor C2, a change in voltage of the fifth node N5 may cause a change in storage voltages of the first capacitor C1 and the second capacitor C2.

In some embodiments, as shown in FIG. 12, the display substrate 100 includes a substrate 1, a semiconductor layer 2, a plurality of gate layers 3, and a plurality of source-drain conductive layers 4. The plurality of source-drain conductive layers 4 may be collectively referred to as functional film layers in the display substrate 100. Each functional film layer includes setting conductive pattern(s), and adjacent functional film layers are separated by an insulating film layer.

For example, the substrate 1 may be a rigid substrate, and a material of the rigid substrate includes but is not limited to glass. Alternatively, the substrate 1 may be a flexible substrate, and a material of the flexible substrate includes but is not limited to any one of polyimide (PI), polycarbonate (PC) or polyvinyl chloride (PVC).

For example, as shown in FIGS. 12 and 13, the semiconductor layer 2 includes an active layer pattern. As shown in FIG. 13, the active layer pattern includes active layers of transistors TFT.

In some examples, the thin film transistor TFT may be a low temperature polysilicon thin film transistor. That is, the semiconductor layer 2 is made of low temperature polysilicon.

In some other examples, the thin film transistor TFT may be an oxide thin film transistor. That is, the semiconductor layer 2 is made of metal oxide, such as indium gallium zinc oxide or indium gallium tin oxide.

In some embodiments, as shown in FIG. 12, the plurality of gate layers 3 includes a first gate layer 31 and a second gate layer 32 arranged in sequence on a side of the substrate 1.

For example, as shown in FIG. 14, the first gate layer 31 includes a first gate conductive pattern. Orthogonal projections, on the substrate 1, of the first gate conductive pattern and the active layer pattern overlap, and portions of the first gate conductive pattern overlapping with the active layer pattern is used as gates of the transistors TFT.

In some examples, as shown in FIG. 14, the first gate conductive pattern includes a scan signal line Scan extending in the first direction X, and the scan signal line Scan is configured to transmit a scan signal to transistors TFT.

In some embodiments, as shown in FIGS. 12 and 14, the second gate layer 32 includes a second gate conductive pattern, and the second gate conductive pattern includes auxiliary reference voltage signal line(s) VRef11.

For example, as shown in FIG. 14, the auxiliary reference voltage signal line VRef11 extends in the first direction X, and is connected to reference voltage signal lines VRef1.

For example, as shown in FIG. 14, the second gate conductive pattern includes a plurality of signal lines extending in the first direction X, such as the auxiliary reference voltage signal line(s) VRef11, the second reference voltage signal lines VRef2, the first initialization signal lines Vinit1, the second enable signal lines EM2, and repair signal line(s) Repair. The first initialization signal line Vinit1 is configured to transmit an initialization signal to transistors TFT. The second enable signal line EM2 is configured to transmit a light-emitting control signal to transistors TFT.

In some embodiments, as shown in FIG. 12, the display substrate 100 further includes a plurality of gate insulating layers 5. The plurality of gate insulating layers 5 include: a first gate insulating layer 51 disposed between the semiconductor layer 2 and the first gate layer 1, and a second gate insulating layer 52 disposed between the first gate layer 31 and the second gate layer 32.

In some embodiments, as shown in FIG. 14, the first gate conductive pattern includes a first plate pattern, and the first plate pattern includes first plates of capacitors (e.g., the first capacitor C1 and the second capacitor C2) of each pixel circuit 10 (e.g., the first plate C11 of the first capacitor C1 and the first plate C21 of the second capacitor C2). The second gate layer 32 further includes a second plate pattern. The second plate pattern includes second plates of the capacitors of each pixel circuit 10 (e.g., the second plate C12 of the first capacitor C1 and the second plate C22 of the second capacitor C2).

As shown in FIG. 14, orthogonal projections, on the substrate 1, of the first electrode pattern and the second electrode pattern overlap. The second plate C12 and the first plate C11 of the first capacitor C1 overlap to form the first capacitor C1, and the second plate C22 and the first plate C21 of the second capacitor C2 overlap to form the second capacitor C2.

In some embodiments, as shown in FIGS. 3, 4 and 12, a pair of adjacent source-drain conductive layers 4 among the plurality of source-drain conductive layers 4 include a first setting source-drain conductive layer and a second setting source-drain conductive layer. The first setting source-drain conductive layer is closer to the substrate 1 than the second setting source-drain conductive layer. The first fan-out line FIP1 is arranged in the first setting source-drain conductive layer. The data lines DL and the second fan-out line FIP2 are arranged in the second setting source-drain conductive layer.

For example, as shown in FIG. 15, an insulating dielectric layer ILD is provided between the second gate layer 32 and a first source-drain conductive layer 41; the second gate layer 32 and the first source-drain conductive layer 41 are electrically insulated; the insulating dielectric layer ILD is provided therein with via holes; and a portion of the second gate conductive pattern in the second gate layer 32 and a portion of a first conductive pattern in the first source-drain conductive layer 41 that need to be connected are electrically connected through a via hole in the insulating dielectric layer ILD.

For example, an insulating separation layer (e.g., a planarization layer 6) is provided between the first setting source-drain conductive layer and the second setting source-drain conductive layer; the first setting source-drain conductive layer and the second setting source-drain conductive layer are electrically insulated; the insulating separation layer is provided therein with via holes; and a portion of the first setting source-drain conductive layer and a portion of the second setting source-drain conductive layer that need to be connected may be electrically connected through a via hole in the insulating separation layer. An end of the first fan-out line FIP1 is connected to the setting data line DL1 through a via hole, and another end of the first fan-out line FIP1 is connected to the second fan-out line FIP2 through another via hole.

The first setting source-drain conductive layer includes the first fan-out line(s) FIP1 extending in the first direction X, and may further include other signal lines extending in the first direction X. The second setting source-drain conductive layer includes the second fan-out line(s) FIP2 and the data lines DL extending in the second direction Y, and may further include other signal lines extending in the second direction Y. In this way, multiple signal lines included in each source-drain conductive layer may all extend in the same direction, which simplifies structures of conductive patterns, and in turn simplifies the process of forming the source-drain conductive layer.

In addition, due to the first fan-out lines FIP1 and the second fan-out lines FIP2, data lines DL (setting data lines DL1) located on two sides of the display region AA in the first direction X may be led out from the display region AA to the bonding region. Therefore, the width of the portion, where the bonding region BB is located, of the peripheral region AN of the display substrate 100 is reduced, and the width of the border of the display apparatus 1000 for bonding the driver is reduced.

As shown in FIGS. 14 and 15, the first fan-out line FIP1 is arranged in the first setting source-drain conductive layer, and the auxiliary reference voltage signal line VRef11 is located in the second gate layer 32. In the thickness direction of the display substrate 100, the auxiliary reference voltage signal line VRef11 is located above the fifth node N5, and the first fan-out line FIP1 is located above the auxiliary reference voltage signal line VRef11. That is, the auxiliary reference voltage signal line VRef11 is located between the fifth node N5 and the first fan-out line FIP1.

The auxiliary reference voltage signal line VRef11 is configured to transmit an auxiliary reference voltage signal, and the auxiliary reference voltage signal is a constant voltage signal. In this way, the auxiliary reference voltage signal line VRef11 between the fifth node N5 and the first fan-out line FIP1 plays a shielding role to prevent signal crosstalk between the data signal transmitted on the first fan-out line FIP1 and the fifth node N5, thus ensuring the normal operation of the pixel circuit 10.

In some embodiments, as shown in FIGS. 3 and 4, the plurality of source-drain conductive layer 4 include a first source-drain conductive layer 41 and a second source-drain conductive layer 42. The first source-drain conductive layer 41 is the first setting source-drain conductive layer, and the second source-drain conductive layer 42 is the second setting source-drain conductive layer.

For example, the first fan-out line(s) FIP1 are arranged in the first source-drain conductive layer 41, and the data lines DL and the second fan-out line(s) FIP2 are arranged in the second source-drain conductive layer 42.

For example, as shown in FIG. 15, the first source-drain conductive layer 41 includes a first source-drain conductive pattern, and the first source-drain conductive pattern includes a source electrode 411 and a drain electrode 412 of each transistor TFT. The source 411 and the drain 412 may be the same in structure, and therefore the source 411 and the drain 412 of the transistor TFT may be interchanged.

For example, as shown in FIG. 15, the first source-drain conductive pattern further includes first gate lines GL1, second gate lines GL2, third gate lines GL3, first fan-out line(s) FIP1, auxiliary second voltage signal line(s) DIP, auxiliary first voltage signal line(s) SIP and first enable signal lines EM1 that all extend in the first direction X. The first enable signal line EM1 is configured to transmit a light-emitting control signal to transistors TFT.

Referring to FIGS. 14 and 15, the second plate C22 of the second capacitor C2 is provided therein with an opening, and the first source-drain conductive layer 41 further includes a connection line LX, an end of the connection line LX is connected to the first plate C21 of the second capacitor C2 through the opening, and another end of the connection line LX is connected to the fifth node N5 in the dotted box as shown in FIG. 14.

Referring to FIGS. 14 and 15, in the thickness direction of the display substrate 100, the auxiliary reference voltage signal line VRef11 is located above the fifth node N5, and the first fan-out line FIP1 is located above the auxiliary reference voltage signal line VRef11. That is, the auxiliary reference voltage signal line VRef11 is located between the fifth node N5 and the first fan-out line FIP1.

The auxiliary reference voltage signal line VRef11 is configured to transmit an auxiliary reference voltage signal, and the auxiliary reference voltage signal is a constant voltage signal. In this way, the auxiliary reference voltage signal line VRef11 between the fifth node N5 and the first fan-out line FIP1 plays a shielding role to prevent signal crosstalk between the data signal transmitted on the first fan-out line FIP1 and the fifth node N5, thus ensuring the normal operation of the pixel circuit 10.

For example, as shown in FIG. 12, the display substrate 100 further includes: a plurality of planarization layers 6. The plurality of planarization layers 6 include a first planarization layer 61 and a second planarization layer 62. The first planarization layer 61 is disposed between the first source-drain conductive layer 41 and the second source-drain conductive layer 42. The second planarization layer 62 is disposed on a side of the second source-drain conductive layer 42 away from the first source-drain conductive layer 41.

In some embodiments, as shown in FIGS. 3 and 4, the second source-drain conductive layer 42 includes data lines DL, first voltage signal lines VSS, second voltage signal lines VDD, second fan-out lines FIP2 and reference voltage signal lines VRef1 that all extend in the second direction Y.

For example, as shown in FIG. 8, the first planarization layer 61 is provided therein with a plurality of via holes. The first voltage signal line VSS is electrically connected to the auxiliary first voltage signal line SIP through a via hole in the first planarization layer 61. Therefore, the number of signal lines for transmitting the first voltage signal in the display region AA is increased without increasing a film layer, the wiring density of the signal lines for transmitting the first voltage signal in the display region AA is increased, and the resistance of the first voltage signal lines VSS is reduced.

For example, as shown in FIG. 8, the second voltage signal line VDD is electrically connected to the auxiliary first voltage signal line DIP through a via hole in the first planarization layer 61. Therefore, the number of signal lines for transmitting the second voltage signal in the display region AA is increased without increasing a film layer, the wiring density of the signal lines for transmitting the second voltage signal in the display region AA is increased, and the resistance of the second voltage signal lines VDD is reduced.

In some embodiments, the plurality of source-drain conductive layers 4 include a first source-drain conductive layer 41, a second source-drain conductive layer 42 and a third source-drain conductive layer 43. The first source-drain conductive layer 41 is the first setting source-drain conductive layer, and the second source-drain conductive layer 42 is the second setting source-drain conductive layer.

For example, the first fan-out line(s) FIP1 are arranged in the first source-drain conductive layer 41, and the data lines DL and the second fan-out line(s) FIP2 are arranged in the second source-drain conductive layer 42.

For example, as shown in FIG. 12, the plurality of planarization layers 6 further include a third planarization layer 63 disposed on a side of the third source-drain conductive layer 43 away from the second source-drain conductive layer 42.

In some embodiments, the plurality of source-drain conductive layers 4 include a first source-drain conductive layer 41, a second source-drain conductive layer 42 and a third source-drain conductive layer 43. The second source-drain conductive layer 42 is the first setting source-drain conductive layer, and the third source-drain conductive layer 43 is the second setting source-drain conductive layer.

For example, the second source-drain conductive layer 42 is the first setting source-drain conductive layer, and the third source-drain conductive layer 43 is the second setting source-drain conductive layer. The first fan-out line(s) FIP1 are arranged in the second source-drain conductive layer 42, and the data lines DL and the second fan-out line(s) FIP2 are arranged in the third source-drain conductive layer 43.

It will be noted that the display substrate 100 may include two semiconductor layers, a material of one semiconductor layer includes, for example, low-temperature polysilicon, and a material of another semiconductor layer includes, for example, metal oxide. Active layers of the plurality of transistors TFT included in the pixel circuit 10 are located in the two semiconductor layers. In this way, the plurality of transistors TFT included in the pixel circuit 10 include some low-temperature polysilicon thin film transistors and some oxide thin film transistors.

In some embodiments, as shown in FIGS. 14 and 15, the display substrate 100 further includes a plurality of auxiliary reference voltage signal lines VRef11 disposed on a side of the semiconductor layer 2 away from the substrate 1. The auxiliary reference voltage signal line VRef11 extends in the first direction X and is electrically connected to the reference voltage signal line VRef1. The first fan-out line FIP1 is disposed on a side of the auxiliary reference voltage signal line VRef11 away from the substrate 1. Orthogonal projections, on the substrate 1, of the first fan-out line FIP1 and the auxiliary reference voltage signal line VRef11 overlap; and orthogonal projections, on the substrate 1, of the first fan-out line FIP1 and a part of the semiconductor layer 2 overlap.

In the thickness direction of the display substrate 100, the auxiliary reference voltage signal line VRef11 is located above the fifth node N5, and the first fan-out line FIP1 is located above the auxiliary reference voltage signal line VRef11. That is, the auxiliary reference voltage signal line VRef11 is located between the fifth node N5 and the first fan-out line FIP1. In this way, the auxiliary reference voltage signal transmitted by the auxiliary reference voltage signal line VRef11 is a constant voltage signal, and the auxiliary reference voltage signal line VRef11 plays a shielding role to prevent signal crosstalk between the data signal transmitted on the first fan-out line FIP1 and the fifth node N5, thus ensuring the normal operation of the pixel circuit 10.

It will be noted that the first fan-out line FIP1 extends in the first direction X, and the first fan-out line FIP1 and each fifth node N5 of a row of pixel circuits 10 adjacent thereto have a shielding structure therebetween, so as to prevent signal crosstalk between the data signal transmitted by the first fan-out line FIP1 and the fifth node N5 of the pixel circuit 10. A shielding structure may be an auxiliary reference voltage signal line VRef11 located between the first fan-out line FIP1 and the fifth node N5 in the thickness direction of the display substrate 100, or may be an other signal line transmitting a constant voltage signal.

In some embodiments, as shown in FIGS. 6 and 7, the display substrate 100 further includes a plurality of second voltage signal lines VDD. The second voltage signal lines VDD extend in the second direction Y. A column of pixel circuits 10 is electrically connected to a second voltage signal line VDD.

A film layer where the plurality of second voltage signal lines VDD are located is located on a side, away from the substrate 1, of a film layer where the first fan-out line(s) FIP1 are located. An orthogonal projection of the second voltage signal line VDD on the substrate 1 covers an orthogonal projection of the first disconnected opening DK1 of the first fan-out line FIP1 on the substrate 1.

For example, as shown in FIGS. 6 and 7, the first fan-out line FIP1 is located in the first source-drain conductive layer 41, and the second voltage signal line VDD is located in the second source-drain conductive layer 42. An orthogonal projection of the first disconnected opening DK1 of the first fan-out line FIP1 on the substrate 1 is located within an orthogonal projection of the second voltage signal line VDD on the substrate 1. That is, the second voltage signal line VDD blocks the first disconnected opening DK1. When the ambient light from a side of the substrate 1 away from the first source-drain conductive layer 41 irradiates on the substrate 1, a part of the ambient light directed to a part of the first fan-out line FIP1 where no disconnected opening DK1 is arranged may be blocked and reflected by the part of first fan-out line FIP1, and a part of the ambient light directed to the first disconnected opening DK1 may be blocked and reflected by the second voltage signal line VDD. Therefore, the difference between light reflectivity of the first source-drain conductive layer 41 at the position where the first disconnected opening DK1 is arranged and light reflectivity of the first source-drain conductive layer 41 at the position where no first disconnected opening DK1 is arranged is reduced, and the screen-off mura phenomenon caused by the first disconnected opening DK1 is effectively weakened.

For example, the number of second disconnected openings DK2 of the second fan-out line FIP2 is greater than or equal to the number of first disconnected openings DK1 of the first fan-out line FIP1.

In some examples, as shown in FIGS. 5, 6 and 7, for one first fan-out line FIP1 and one second fan-out line FIP2 that are connected to the setting data line DL1, the number of second disconnected openings DK2 of the second fan-out line FIP2 is half the number of first disconnected openings DK1 of the first fan-out line FIP1. For example, each first fan-out line FIP1 is provided therein with two first disconnected openings DK1, and each second fan-out line FIP2 is provided therein with one second disconnected opening DK2.

In some other examples, for one first fan-out line FIP1 and one second fan-out line FIP2 that are connected to the setting data line DL1, the number of second disconnected openings DK2 of the second fan-out line FIP2 is equal to the number of first disconnected openings DK1 of the first fan-out line FIP1. For example, each first fan-out line FIP1 is provided therein with one first disconnected opening DK1, and each second fan-out line FIP2 is provided therein with one second disconnected opening DK2.

It will be understood that, referring to FIGS. 3 and 5, a length of the first fan-out line FIP1 in the first direction X is, for example, the same or approximately the same as a length of the display region AA in the first direction X, and a length of the second fan-out line FIP2 in the second direction Y is, for example, the same or approximately the same as a length of the display region AA in the second direction Y. An end of the effective portion FIP21 of the second fan-out line FIP2 extends to the bonding region BB, and another end of the effective portion FIP21 extends toward the display region AA in the second direction Y and is connected to an end of the effective portion FIP11 of the first fan-out line FIP1. Another end of the effective portion FIP11 of the first fan-out line FIP1 is connected to a single setting data line DL1.

In a case where no other signal lines are arranged between a setting data line DL1 and a border of the display region AA that extends in the second direction Y, a first fan-out line FIP1 connected to the setting data line DL1 may be provided therein with one first disconnected opening DK1.

In a case where other signal lines (such as a first voltage signal line VSS or a second voltage signal line VDD) are arranged between a setting data line DL1 and a border of the display region AA that extends in the second direction Y, a first fan-out line FIP1 connected to the setting data line DL1 may be provided therein with two first disconnected openings DK1, and the two first disconnected openings DK1 are respectively disposed on two sides of the setting data line DL1 in the first direction X. In this way, the first fan-out line FIP1 has two redundant portions FIP12, and the two redundant portions FIP12 may be respectively connected to two signal lines (e.g., first voltage signal lines VSS or second voltage signal lines VDD), so as to increase the wiring density of signal lines connected to the redundant portions FIP12 in the display region AA, and in turn reduce the resistance of the signal lines connected to the redundant portions FIP12.

The disconnected opening(s) of the first fan-out line FIP1 and the disconnected opening(s) of the second fan-out line FIP2 may be adaptively designed according to actual needs. This is only an exemplary description and is not intended to limit the present disclosure.

In some embodiments, as shown in FIGS. 3, 4 and 6, the display substrate 100 further includes gate signal lines GL, enable signal lines EM, auxiliary first voltage signal line(s) SIP and auxiliary second voltage signal line(s) DIP that all extend in the first direction X. The pixel circuit 10 is electrically connected to gate signal lines GL1 and enable signal lines EM. The auxiliary first voltage signal line SIP is electrically connected to the first voltage signal line VSS, and the auxiliary second voltage signal line DIP is electrically connected to the second voltage signal line VDD.

At least one of the gate signal lines GL, the enable signal lines EM, the auxiliary first voltage signal line(s) SIP and the auxiliary second voltage signal line(s) DIP is arranged in the first setting source-drain conductive layer. An orthogonal projection, on the substrate 1, of at least one of a gate signal line GL1, an enable signal line EM, an auxiliary first voltage signal line SIP and an auxiliary second voltage signal line DIP covers an orthogonal projection, on the substrate 1, of the second disconnected opening DK2 of the second fan-out line FIP2.

For example, the enable signal lines EM include a first enable signal line EM1 and a second enable signal line EM2. The pixel circuit 10 is electrically connected to the first enable signal line EM1 and the second enable signal line EM2.

In the case where the display substrate 100 includes two source-drain conductive layers 4, the first setting source-drain conductive layer is the first source-drain conductive layer 41. In the case where the display substrate 100 includes three source-drain conductive layers 4, the first setting source-drain conductive layer is the first source-drain conductive layer 41 or the second source-drain conductive layer 42. The following description is introduced by taking an example in which the first setting source-drain conductive layer is the first source-drain conductive layer 41 and the second setting source-drain conductive layer is the second source-drain conductive layer 42.

At least one of the gate signal lines GL, the enable signal lines EM, the auxiliary first voltage signal line(s) SIP and the auxiliary second voltage signal line(s) DIP is located in the first setting source-drain conductive layer, the second fan-out line FIP2 is located in the second setting source-drain conductive layer, and the first setting source-drain conductive layer is located between the second setting source-drain conductive layer and the substrate 1. In this way, when at least one of the gate signal line GL, the enable signal line EM, the auxiliary first voltage signal line SIP and the auxiliary second voltage signal line DIP in the first setting source-drain conductive layer covers the second disconnected opening DK2 of the second fan-out line FIP2, it has a signal shielding effect, thereby preventing the data signal transmitted by the second fan-out line FIP2 passing through a region between pixel circuits 10 of adjacent sub-pixels P(x) from generating signal crosstalk with nodes in the pixel circuit 10, and in turn ensuring the normal operation of the pixel circuit 10.

As shown in FIG. 6, a horizontal signal line, which overlaps the second disconnected opening DK2, in the first source-drain conductive layer 41 may be at least one of the gate signal line GL1, the enable signal line EM, the auxiliary first voltage signal line SIP or the auxiliary second voltage signal line DIP.

In some embodiments, as shown in FIGS. 12 and 15, the first voltage signal lines VSS, the second voltage signal lines VDD, and the reference voltage signal lines VRef1 in the display substrate 100 are all arranged in the second setting source-drain conductive layer.

The first voltage signal line VSS, the second voltage signal line VDD and the reference voltage signal line VRef1 in the second setting source-drain conductive layer may block the first disconnected opening DK1 of the first fan-out line FIP1 in the first setting source-drain conductive layer, so as to prevent signal crosstalk between the data signal transmitted by the first fan-out line FIP1 and the node of the pixel circuit 10 at the first disconnected opening DK1, and in turn ensure the normal operation of the pixel circuit 10.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display substrate, having a display region and a bonding region, the bonding region being located on a side of the display region in a second direction;
the display substrate comprising:
a plurality of pixel circuits arranged in a plurality of rows and a plurality of columns, wherein a row of pixel circuits is arranged in a first direction, and a column of pixel circuits is arranged in the second direction, the first direction and the second direction intersecting;
a plurality of data lines extending in the second direction, the column of pixel circuits being electrically connected to one of the data lines; and
first fan-out lines and second fan-out lines that are disposed in the display region, wherein the first fan-out lines extend in the first direction, and the second fan-out lines extend in the second direction; the plurality of data lines include at least one setting data line, and the second fan-out lines are closer to a center line, along the second direction, of the bonding region than the at least one setting data line; an end of a first fan-out line is electrically connected to a setting data line of the at least one setting data line, and another end of the first fan-out line is electrically connected to a second fan-out line;
wherein the display substrate comprises a plurality of pixels, each pixel includes at least three sub-pixels, and each sub-pixel includes one pixel circuit; the plurality of pixels include at least one setting pixel, and one setting pixel corresponds to at least one of the second fan-out lines; and a second fan-out line passes through a region between pixel circuits of two adjacent sub-pixels in a corresponding setting pixel or passes through an outer side of an outer pixel circuit of the corresponding setting pixel, and extends to the bonding region.

2. The display substrate according to claim 1, further comprising:
first voltage signal lines extending in the second direction, wherein the setting pixel corresponds to at least one of the first voltage signal lines; and a first voltage signal line passes through a region between pixel circuits of two adjacent sub-pixels in a corresponding setting pixel or passes through an outer side of an outer pixel circuit of the corresponding setting pixel.

3. The display substrate according to claim 2, wherein one second fan-out line among the at least one of the second fan-out lines corresponding to the setting pixel passes through a region between pixel circuits of a pair of adjacent sub-pixels in the setting pixel, and one first voltage signal line among the at least one of the first voltage signal lines corresponding to the setting pixel passes through a region between pixel circuits of another pair of adjacent sub-pixels in the setting pixel.

4. The display substrate according to claim 3, wherein the pixel includes three sub-pixels;
the setting pixel corresponds to one second fan-out line and one first voltage signal line, the second fan-out line passes through a region between pixel circuits of a pair of adjacent sub-pixels among three sub-pixels in the setting pixel, and the first voltage signal line passes through a region between pixel circuits of another pair of adjacent sub-pixels among the three sub-pixels in the setting pixel.

5. The display substrate according to claim 2, wherein one first voltage signal line among the at least one first voltage signal line corresponding to the setting pixel and one second fan-out line among the at least one second fan-out line corresponding to the setting pixel pass through a region between pixel circuits of a same pair of adjacent sub-pixels.

6. The display substrate according to claim 5, wherein the pixel includes three sub-pixels;
the setting pixel corresponds to one second fan-out line and one first voltage signal line, and the second fan-out line and the first voltage signal line pass through a region between pixel circuits of a same pair of adjacent sub-pixels among three sub-pixels in the setting pixel.

7. The display substrate according to claim 5, wherein the second fan-out line is provided therein with a second disconnected opening, and the second disconnected opening divides the second fan-out line into an effective portion and a redundant portion; an end of the effective portion of the second fan-out line is electrically connected to the first fan-out line, and another end of the effective portion of the second fan-out line extends to the bonding region;
the display substrate further comprises a first connection portion; and the first voltage signal line and the redundant portion of the second fan-out line are electrically connected through the first connection portion.

8. The display substrate according to claim 7, wherein the first voltage signal line and the second fan-out line passing through the region between the pixel circuits of the same pair of adjacent sub-pixels are adjacent to each other; and the first voltage signal line, the second fan-out line and the first connection portion are arranged in the same layer and constitute a one-piece structure.

9. The display substrate according to claim 7, wherein the first fan-out line is provided therein with a first disconnected opening, and the first disconnected opening divides the first fan-out line into an effective portion and a redundant portion; an end of the effective portion of the first fan-out line is electrically connected to the setting data line, and another end of the effective portion of the first fan-out line is electrically connected to the effective portion of the second fan-out line;
the display substrate further comprises a second connection portion; an end of the second connection portion is electrically connected to the redundant portion of the first fan-out line; in a thickness direction of the display substrate, a via hole is provided between the second connection portion and the redundant portion of the second fan-out line; and another end of the second connection portion is electrically connected to the redundant portion of the second fan-out line through the via hole.

10. The display substrate according to claim 9, wherein the second connection portion and the redundant portion of the first fan-out line are arranged in the same layer and constitute a one-piece structure.

11. The display substrate according to claim 1, further comprising:
a plurality of reference voltage signal lines extending in the second direction, wherein the column of pixel circuits is electrically connected to one of the reference voltage signal lines; among two adjacent columns of pixel circuits, a reference voltage signal line connected to one column of pixel circuits and a data line connected to another column of pixel circuits are arranged close to each other;
wherein a second fan-out line is arranged between the reference voltage signal line and the data line that are arranged close to each other.

12. The display substrate according to claim 11, wherein a first voltage signal line in the display substrate is arranged between the reference voltage signal line and the data line that are arranged close to each other.

13. The display substrate according to claim 11, further comprising:
a substrate;
a semiconductor layer disposed on the substrate; and
a plurality of auxiliary reference voltage signal lines disposed on a side of the semiconductor layer away from the substrate, an auxiliary reference voltage signal line extending in the first direction and being electrically connected to a reference voltage signal line;
wherein a first fan-out line is arranged on a side of the auxiliary reference voltage signal line away from the substrate; and an orthogonal projection of the first fan-out line on the substrate overlaps with an orthogonal projection of the auxiliary reference voltage signal line on the substrate, and overlaps with an orthogonal projection of a part of the semiconductor layer on the substrate.

14. The display substrate according to claim 1, further comprising:
a substrate; and
a plurality of second voltage signal lines extending in the second direction, wherein the column of pixel circuits is electrically connected to one of the second voltage signal lines;
wherein a film layer where the plurality of second voltage signal lines are located is located on a side, away from the substrate, of a film layer where the first fan-out lines are located; and an orthogonal projection of the second voltage signal line on the substrate covers an orthogonal projection of a first disconnected opening of the first fan-out line on the substrate.

15. The display substrate according to claim 1, further comprising:
a substrate; and
a plurality of source-drain conductive layers, wherein a pair of adjacent source-drain conductive layers among the plurality of source-drain conductive layers includes a first setting source-drain conductive layer and a second setting source-drain conductive layer, and the first setting source-drain conductive layer is closer to the substrate than the second setting source-drain conductive layer;
wherein the first fan-out lines are arranged in the first setting source-drain conductive layer, and the data lines and the second fan-out lines are arranged in the second setting source-drain conductive layer.

16. The display substrate according to claim 15, further comprising: a gate signal line, an enable signal line, an auxiliary first voltage signal line and an auxiliary second voltage signal line that all extend in the first direction, wherein the pixel circuit is electrically connected to the gate signal line and the enable signal line; the auxiliary first voltage signal line is electrically connected to a first voltage signal line, and the auxiliary second voltage signal line is electrically connected to a second voltage signal line;
at least one of the gate signal line, the enable signal line, the auxiliary first voltage signal line and the auxiliary second voltage signal line is arranged in the first setting source-drain conductive layer; an orthogonal projection, on the substrate, of at least one of the gate signal line, the enable signal line, the auxiliary first voltage signal line and the auxiliary second voltage signal line covers an orthogonal projection, on the substrate, of a second disconnected opening of the second fan-out line.

17. The display substrate according to claim 15, wherein first voltage signal lines, second voltage signal lines and reference voltage signal lines in the display substrate are all arranged in the second setting source-drain conductive layer; and/or
the display substrate further comprises a first gate layer and a second gate layer, wherein in the display substrate, a semiconductor laver, the first gate layer and the second gate laver are arranged in sequence in action away from the substrate and are located between the substrate and the plurality of source-drain conductive layers; and auxiliary reference voltage signal lines in the display substrate are arranged in the second gate layer.

18. (canceled)

19. The display substrate according to claim 15, wherein
the plurality of source-drain conductive layers include a first source-drain conductive layer and a second source-drain conductive layer, the first source-drain conductive layer is the first setting source-drain conductive layer, and the second source-drain conductive layer is the second setting source-drain conductive layer; or
the plurality of source-drain conductive layers include a first source-drain conductive layer, a second source-drain conductive layer and a third source-drain conductive layer, the first source-drain conductive layer is the first setting source-drain conductive layer, and the second source-drain conductive layer is the second setting source-drain conductive layer; or
the plurality of source-drain conductive layers include a first source-drain conductive layer, a second source-drain conductive layer and a third source-drain conductive layer, the second source-drain conductive layer is the first setting source-drain conductive layer, and the third source-drain conductive layer is the second setting source-drain conductive layer.

20. The display substrate according to claim 1, wherein the at least one setting data line is farther away from the center line, along the second direction, of the bonding region than remaining data lines among the plurality of data lines; the at least one setting data line are entirely located in the display region; and ends of the remaining data lines extend to the bonding region.

21. A display apparatus, comprising:
the display substrate according to claim 1; and
a circuit board electrically connected to the display substrate.
